(19) United States
(12) Patent Application Publication
(10) Pub. No.: US 2001/0012067 A1
(43) Pub. Date: Aug. 9, 2001

(54) HIGH DEFINITION TELEVISION PROGRESSIVE SCAN BROADCAST CAMERA

(76) Inventors: STUART M. SPITZER, LYNNFIELD, MA (US); JAMES R. TOKER, CAMBRIDGE, MA (US); SELIM S. BENCUYA, NEWTON, MA (US)

Correspondence Address: POLAROID CORPORATION, PATENT DEPARTMENT, 784 MEMORIAL DRIVE, CAMBRIDGE, MA, 02139, US

(21) Appl. No.: 08/839,687

(22) Filed: Apr. 14, 1997

Related U.S. Application Data
(60) Provisional application No. 60/015,371, filed on Apr. 12, 1996.

(51) Int. Cl. H04N 3/14; H04N 5/335

(52) U.S. Cl. 348/243; 348/297

(57) ABSTRACT

A camera is described which is capable of meeting the United States standards for high definition television (HDTV). The camera produces a display of 1280 pixels by 720 pixels at a rate of 60 frames per second. In the preferred embodiment, there is provided, as an image sensor, a frame transfer three phase buried channel CCD capable of shifting the charge from an imaging region to a storage region within a brief blanking period provided by a shuttered lens. The image sensor has an arrangement of spaced electrodes which are electrically connected to shunts in the image sensor to transport charge, but are also arranged in the imaging region such that the geometry of the electrodes within each of the plurality of pixels is similar and thereby reduce the resistance present during shifting the charge from the imaging region to the storage region. The image sensor further minimizes the effect of dark current from the storage section on a reproduced image, and provides for amplification of the image prior to the introduction of substantial noise. Additional embodiments are described wherein: i) an anti-reflective coating minimizes distortion of the reproduced image without contamination of the camera; ii) the camera is capable of reproducing images at a variable frame rate; and, iii) the image sensor is capable of operating either in a progressive-scan mode or an interlace-scan mode.

### BACKGROUND OF THE INVENTION

This invention relates to a camera such as may be used for a high definition 5 television broadcast camera system and, in particular, to a camera adapted to incorporate an image sensor, such as a solid-state frame transfer (FT) charge coupled device (CCD) having square pixels that can selectively scan progressively and produce a 1280×720 image with high resolution.

CCDs used for an image sensor in imaging systems of the frame transfer type are known in the art. These CCD comprise a plurality of photosensitive portions arranged in columns. In these devices, channels are arranged side by side in parallel columns and are electrically separated by channel stops. Incident light from a scene operates to photo-generate minority charge carriers in the photosensitive portions of the channels. Each charge collected in the photosensitive portions is proportional to an amount of light or radiation of the scene from where the charge was collected. The charge is an electrical representation of the scene.

For such applications, it is necessary to shift minority charge carriers in the photosensitive portions of the CCD to a storage region, such that the photosensitive portions can collect charges of the scene for a subsequent second of a video. A complex system of electrodes that are insulated from the channels effects charge transport along the channels to the storage region, where each of these charges in then stored and transmitted to an output register, which serially reads out the channels from the CCD for further processing.

By way of example, one such application, that of a progressive-scan camera that produces an image of 1080 pixels by 1920 pixels has to transfer each of a 1080 lines of the charge collected by the photosensitive portions to the storage region prior to recollecting charge representative of the next scene. In such an application, the 1080 lines have to be transferred to the storage region during a brief blanking period when the image and the incident light are blocked out by a shuttered lens. As this is the progressive-scan camera, each pixel of the 1080 lines has to be read out during the brief blanking period. Due to the time required to read out all the information stored in the pixels of all 1080 lines this application has only been able to achieve 30 pictures per second known in the art as 30 frames per second. Pictures displayed at 30 frames per second, however, result in flickers discernible to a human eye, and thus this application produces a poor picture. One approach to making a picture without flicker and thus a greater resolution is to increase a scanning rate. An application that has an increased scanning rate is an interlace-scan camera that uses a solid-state CCD and produces pictures in a 1080 by 1920 format. The interlace-scan camera can increase the scanning rate as it only moves one-half of the charge from the pixels of the imaging region to the storage prior to collecting charges from the next scene. Specifically, in the 1080 by 1920 example, only 540 lines of pixels will be read out during each brief blanking period. Each 540 lines is called a field. Two fields must be used to create one complete picture or frame. In this example, each field would be produced at a rate of 60 fields per second, then combined such that one frame, a combination of both fields, would be produced at 30 frames per second. Since a display device would draw 60 fields per second, this application produces pictures that do not have the similar flickers discernible to the human eye. A drawback of this approach, however, is that using two fields to make one complete frame combines two partial images taken at different times. This results in misregistration and low resolution when the scene moves. Also, in the display device the alternation between the two partial images results in detailed flickering 30 times per second along detailed edges.

Another drawback of the conventional progressive-scan cameras is that a solid-state camera has not been produced that is compatible with the proposed US HDTV standards for a progressive-scan of 750 lines at 60 frames per second.

Another problem with the interlace-scan and progressive-scan cameras are its methods employed for minimizing reflection from any regions located near the photosensitive portions of the CCD. Light incident on the CCD will hit not only the photosensitive portions but also the regions proximate to the photosensitive portions. When the regions proximate to the photosensitive portions are reflective, the incident light will hit these reflective regions and reflect light around the CCD. Reflected light may enter the photosensitive portions and distort the charge collected in each pixel of the CCD, thus altering the resulting picture. In order to overcome this obstacle, many applications cover non-photosensitive portions of the CCD with a dark substance. The dark substance is not always compatible with manufacturing of the CCDs and other semiconductors for contamination reasons or owing to health and environmental concerns. Thus, while the dark substance may solve the reflected light problem, it introduces a host of other issues.

A further drawback with the current CCD interlace-scan and progressive-scan cameras are owing to a distortion of the image caused by generation of dark current in the storage region. As previously described, the electrodes effect charge transport along the channels. In the storage region, as each charge is transferred from a previous row pixels to a next row of pixels down the channels, the charge accumulates a delta of charge representative of a dark current from each row of pixels in the storage region. In conventional cameras, the charge in the storage region is subjected to current that flows through the camera in total darkness. This current is known as dark current. The dark current is a function of a geometry of the electrodes and an applied voltage to the electrodes. The dark current increases with the applied voltage.

An effect of the dark current, a delta of charge, is aggravated by the geometry of the electrodes in the conventional cameras. In order to provide proper operation the geometry of the electrodes is changed, such that portions of one of the electrodes in a pixel may be enlarged to increase a surface area of the electrodes. The increase in the surface area of an enlarged portion allows a shunt to contact the electrode. At the same time, portions of a different one of the electrodes are enlarged in another pixel, again to increase the surface area. This irregular geometry and the increase in the surface area covered by the electrodes increase a voltage associated with the electrode and thus increase the dark current.

As charge passes from the previous row of pixels to the next row of pixels through the channel, the charge picks up the dark current from the previous row. At the end of the storage region, the charge so transferred contains a delta of charge collected from the dark current of each of the electrodes it has passed. As the channels contain a different total area of at least one of the electrodes owing to the enlarged portions, the dark current varies among the channels and causes streaks in the reproduced image.

Once the charge is transferred from the storage region to an output register the charge is converted into a signal and then processed through the camera prior to transmission to a video tape, a cathode ray tube, or an antenna, for example. The signal is amplified by the camera. Application of amplification, however, amplifies not only the signal representative of each frame, but also it will amplify any noise created by any processing. The noise that is amplified produces a lower signal-to-noise ratio. Thus, a draw back of the conventional cameras is the lower signal-to-noise ratio.

A still further drawback of the conventional cameras is an inability to alter frame rate and thereby facilitate options such as, for example, slow motion or fast motion. In conventional cameras, when a slow motion format is desired the image is filmed by the camera at the frame rate of that camera and then later sped up or slowed down accordingly during post-processing. Thus, to produce a 45 frame per second film using the interlace-scan camera that produces 30 frames per second example, the image is filmed at 30 frames per second and then post-processed to produce the fast motion effect of 45 frames per second.

Traditionally, electronic cameras set their frame rate by choosing a pixel frequency for a pixel clock, and deriving a line time and a frame rate from the pixel clock in fixed relationships. To vary the frame rate the electronic cameras vary the pixel frequency. The drawback of this approach is that it requires many other circuit characteristics, such as bandwidth, to change in proportion. These characteristics are usually difficult to change while obtaining maximum performance at reasonable costs.

A further problem of conventional cameras is that conventional cameras are unable to produce footage for use in a variety of applications and industries, such as computers, movies, facsimiles or other unknown video formats. For instance, a movie format that requires 24 frames per second cannot be achieved by using a conventional camera for television, which produces pictures at 30 frames per second.

Accordingly, it is an object of this invention to provide a solid-state camera capable of generating a high resolution picture in a progressive format such that it is compatible with the proposed US HDTV standards for the progressive format.

It is another object of the invention to provide an image sensor capable of transferring charge from the imaging region to the storage region during the brief blanking period while producing a high-resolution image.

It is a further object of this invention to provide an image sensor that minimizes the effect of dark current.

It is still a further object of this invention to provide an image sensor with minimal reflective regions and with minimal contamination problems.

It is another object of the present invention to provide a camera that improves the signal-to-noise ratio.

It is another object of the invention to provide a camera that can produce a variable frame rate without post-processing.

It is still another object of the invention to provide a camera compatible with different industries and applications.

These and other objects of the invention will be obvious and appear hereinafter.

### SUMMARY

The aforementioned and other objects of the invention are achieved by the invention which provides a camera having one or more image sensors disposed therein within a light-proof enclosure. The image sensors are in optical communication with an image-bearing radiation and are adapted to resolve images at a frame rate with a high resolution. In one embodiment, the camera is a progressive-scan camera that produces images at a rate of 60 frames per second.

In the preferred embodiment, channels are arranged in parallel through the sensor through which the charge is transferred. Longitudinally spaced channel stops define the channels and electrically isolate the channels from one another.

The image sensor also has an imaging region adapted to receive the image-bearing radiation on a plurality of pixels disposed in the imaging region. A radiation sensitive material disposed in the plurality of pixels is adapted translate the image-bearing radiation into charge and is disposed in the channels. The image-bearing radiation photo-generates carriers in the radiation sensitive material portions of the channels.

The sensor also has a storage region adjacent the imaging region for storing charge from the imaging region. The charge in the plurality of pixels in the imaging region is transferred to the storage region during a blanking period when a shutter lens of the camera insulates the image sensors from the image-bearing radiation. Charge is transferred from the imaging region to the storage region through the channels such that each of the plurality of pixels in the imaging region is fully depleted of charge during the brief blanking period and then stored in the storage region. The charge is transferred with the assistance of a charge transfer device in electrical communication with the plurality of pixels in the imaging region.

In the preferred embodiment, the charge transfer device includes more than one electrode and shunts. The electrode overlies the radiation sensitive material in layers electrically isolated from each other. An insulator overlies the electrode and provides holes that allow the electrode to selectively contact shunts therethrough. The electrode is responsive to a predefined voltage that is applied to the shunt that each of the electrodes selectively contact. Thus, the layers of electrodes are responsive to the predefined voltage of one of the shunts which each of the electrodes selectively contacts. The shunts are disposed across the plurality of pixels over the channel stops so as to minimize a surface area of radiation sensitive material covered from the image-bearing radiation.

In the preferred embodiment, the charge is transferred in a progressive-scan mode from the 1296 by 730 array of square 10.8 by 10.8 micron pixels of the imaging region to the storage region at a vertical transfer frequency of greater than 1.3 MHz.

To obtain higher vertical transfer frequencies, the resistance of the electrodes in the imaging region is decreased, and thus the time for charge and discharge is correspondingly decreased. The resistance is decreased in part by staggering the electrodes and having a substantially similar geometry for the electrodes within each of the plurality of pixels in the imaging region. Thus, each of the plurality of pixels in the imaging region is optically similar while being electrically different. In the preferred embodiment, the radiation sensitive material and the metal shunts are also formatted in periodic pattern.

In the preferred embodiment, the resistance is further decreased by using aluminum for the shunts and tying a portion of the shunts to buses disposed in the storage region, as well as by tying the busses to package leads disposed in the storage region.

The layout of the plurality of pixels in the imaging region is further designed such that the exposure of the radiation sensitive material is increased. This is achieved, in part, by layering the shunts over the channel stop and thus decreasing the surface area covered by these opaque materials.

In the preferred embodiment, a plurality of pixels in the storage region also comprise more than one electrode, an insulator, shunts and a charge transport material. However, the electrode in the storage region covers a larger surface area of each of the plurality of pixels to increase a charge storage capability. In one embodiment, the electrode is also disposed in a periodic manner.

The charge stored in a plurality of pixels in the storage region is thereafter transported vertically line by line into a transfer register that reads the charge serially for further processing.

The storage region is connected such that a dark current is averaged over a portion of the plurality of pixels, where dark current is generated in the storage region due to a configuration of each of the electrodes, each electrode having a geometry, a phase, and a voltage contributing to the configuration. In the preferred embodiment three phases are used with the electrodes and thus constitute three configurations. Thus, one out of three electrodes will have a voltage associated with it which is additive to the charge stored in each of the plurality of pixels in the storage region due to the configuration. Each electrode will also have a dark current contributing to the configuration owing to the geometry of the more than one electrode within each of the plurality of pixels in the storage region. By transferring charge through nine rows of electrodes such that each charge will encounter each configuration owing to phase and the geometry associated therewith three times the charge that is outputted reflects an average of the charge owing to the dark current. Thus, the charges transferred to the transfer register and out of the image sensor will have less distortion relative to each other owing to the dark current.

In one embodiment the imaging region also has an anti-reflective coating to cover the area around the plurality of pixels. The anti-reflective coating is comprised of two layers, a red filter layer and a blue filter layer. The combination of the red filter layer and the blue filter layer provide a dark coating that absorbs image-bearing radiation incident on the anti-reflective coating. Thus, the anti-reflective coating minimizes the imaging region's exposure to reflected, stray incident radiation without contaminating the image sensor.

Another embodiment further provides a method to enhance voltage of a signal representative of the charge prior to processing the signal. The increase in voltage is effectuated by sense nodes. The sense nodes are located at the terminating end of the transfer registers of the image sensors. Prior to the sense nodes transferring the charge, the sense nodes amplify the voltage associated with the charge by depleting a capacitance of the sense nodes. In this way, the voltage representative of the charge is amplified prior to introduction of noise and thus the signal-to-noise ratio of a reproduced image is improved.

In a further embodiment, the camera is capable of varying a frame rate of a reproduced image. The frame rate is altered by varying a number of line intervals that form each frame. The line intervals are adapted to receive lines such that only a portion of the lines are actively collecting the image-bearing radiation and a portion of the lines is inactive. In one embodiment, the inactive lines are chosen to be periodic, while in another embodiment the inactive lines are chosen to be staggered at varying intervals.

In still another embodiment of the invention, the camera is adapted to be switchable between interlace-scan and progressive-scan modes. In this embodiment, while the camera is functioning in the progressive-scan mode all 730 lines are transported to the storage region from the imaging region and then read out through the transfer registers. In the interlace-scan mode, individual electrodes of the plurality of pixels in the imaging region and the storage region are read out in an even field and an odd field, which is achieved by programming the camera such that the individual electrodes of the plurality of pixels is selectively processed as a portion of the even field or the odd field as is necessary. The even field and the odd field are then treated as in the interlace-scan camera.

In further aspects, this invention provides methods in accordance with the apparatus described above. The aforementioned and other aspects of the invention are evident in the drawings and in the description that follows.

### BRIEF DESCRIPTION OF DRAWINGS

The foregoing and other objects of this invention, the various features thereof,. as well as the invention itself, may be more fully understood from the following description, when read together with the accompanying drawings in which:

FIG. 1 is a block diagram of a camera in accordance with this invention;

FIG. 2A is a cross-sectional view of an image sensor of one embodiment of this invention;

FIG. 2B is an exploded view of an image sensor of one embodiment of this invention;

FIG. 2C is a cross sectional view in the z-direction of an image sensor of FIG. 2A;

FIG. 3 is a top view of an image sensor of one embodiment of this invention;

FIG. 4A is a top view of one of a plurality of pixels on an image sensor of the preferred embodiment of the invention;

FIG. 4B is a cross-sectional view along line C-C′ of the one plurality of pixels in the imaging region in the preferred embodiment of this invention;

FIG. 4C is a cross-sectional view along line D-D of the one plurality of pixels in the imaging region in the preferred embodiment of this invention;

FIG. 5A is a top view of one of a plurality of pixels on an image sensor of another embodiment of the invention;

FIG. 5B is a cross-sectional view along line F-F′ of the one plurality of pixels in the imaging region of FIG. 5A;

FIG. 6A is a circuit diagram of an image sensor showing the interconnections of more than one electrodes in the imaging region to a storage region in accordance with an embodiment of this invention;

FIG. 6B is a timing diagram illustrating the predefined voltage applied to the more than one electrodes in accordance with an embodiment of this invention;

FIG. 6C is a circuit diagram of an image sensor showing the interconnections of more than one electrodes in the storage region in accordance with an embodiment of this invention;

FIG. 7 is a block diagram of a portion of a storage region of an image sensor in accordance with an embodiment of this invention;

FIG. 8A is a top view of the sense node.

FIG. 8B is a cross-sectional view of a sense node in accordance with one embodiment of this invention;

FIG. 8C is a cross-sectional view of a sense node in accordance with another embodiment of the invention;

FIG. 8D is a cross-sectional view of a sense node in accordance with another embodiment of the invention;

FIG. 9A is a top view of a transistor;

FIG. 9B is a cross-sectional view of the transistor of FIG. 7A along line A-A′;

FIG. 9C is a cross-sectional view of the transistor of FIG. 7A along line B-B′;

FIG. 9D is a top view of a portion of the sense nodes in accordance with an embodiment of the invention.;

FIG. 10A is a chart illustrating inputting lines of a plurality of pixels to a sense node of this invention at 60 frames per second;

FIG. 10B is a chart illustrating another embodiment of this invention where lines are input to the sense node to produce a picture with a different frame rate;

FIG. 10C is another chart of an additional embodiment of this invention that illustrates the lines inputted to the sense node at still another frame rate;

FIG. 10D is still another chart of an additional embodiment of this invention that illustrates the lines inputted to the sense node, where lines are in a non-periodic pattern to produce a picture at a frame rate;

FIG. 11A is a block diagram of electrodes of an interlace-scan camera; and

FIG. 11B is a block diagram of the electrodes of a switchable image sensor of one embodiment of the invention.

### DETAILED DESCRIPTION

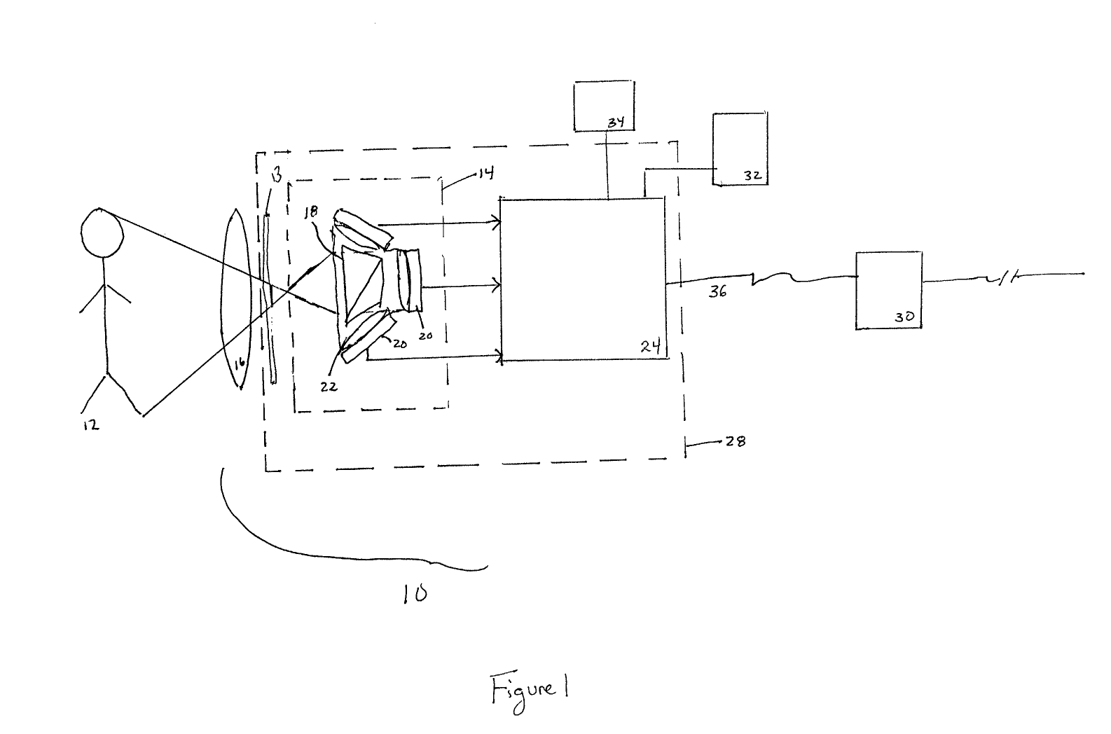

FIG. 1 shows a block diagram of a camera 10 in accordance with one embodiment of the present invention. An optical portion of the camera 10 is enclosed in a light-proof enclosure 14. Optical radiation from the image enters the light-proof enclosure, as image-bearing light corresponding to image 12, through a shuttered lens 16 in the open position. During the operation of camera 10, shuttered lens 16 opens and closes to allow the image-bearing light to enter light-proof enclosure 14. More particularly, a shutter wheel 13 operates to allow the image-bearing light to impinge upon the a beam splitter 18. Other forms of radiation from an image can be collected by the camera 10 without departing from the scope of the invention; the term “light” is used in the preferred embodiment and is illustrative, but not restrictive.

Beam splitter 18 divides the light into three separate beams, as is well-known in the art, each beam focused upon a corresponding image sensor 20. It should be obvious to those skilled in the art that other elements, such as, for example, filters in combination with one or more image sensors, will perform the same function without deviating from the scope of the invention.

The image-bearing light passes through an optical low-pass filter 22 and onto beam splitter 18. Optical low-pass filter 22 is adapted to reduce aliasing, particularly at lower frequencies, by introducing dips or notches in a modulation transfer function (MTF). The MTF of camera 10 is determined by properties of shuttered lens 16, optical low-pass filter 22, and an aperture of a pixel (not shown).

The MTF of camera 10 is a function of the MTF of each of these individual elements. In the preferred embodiment, the MTF of shuttered lens 16 at f/4 is mainly diffraction limited. The MTF of the aperture of the pixel is in the form of a function sin(x)/x. As the aperture of the pixel in this embodiment is large, the MTF of the aperture of the pixel has intrinsically good horizontal and vertical aliasing behavior at higher frequencies. The sample and hold MTF has similar characteristics to the MTF of the aperture of the pixel and is also very good for higher frequencies. However, aliasing is still present at low frequencies. Thus, optical low-pass filter 22 is designed to reduce aliasing especially at lower frequencies.

Optical low-pass filter 22 reduces aliasing by producing dips in the MTF of the camera at the vertical sampling frequency, which in the preferred embodiment is 92.6 line-pairs/mm and at a horizontal sampling frequency, which in the preferred embodiment is at 74.25 MHz or 92.6 line-pairs/mm. Optical low-pass filter 22 achieves the same anti-aliasing effect that is inherent in an interlace-scan camera. In the interlace-scan camera, however, aliasing is reduced owing to an overlap in an odd field and an even field. In this embodiment, however, the optical low-pass filter provides this function, while the absence of a need for the odd and even field allows the camera to produce an image with a higher vertical resolution than is possible with the interlace-scan camera.

Camera 10 can also include other elements prior to optical low-pass filter 22, such as an infrared-filter, a retardation plate, one or more four-position filter wheels, among other elements known in the art depending on a user's choice of features for the camera and other properties of the camera which are well known in the art. Also, as is well known in the art, each element can further have component parts, for example the one or more four-positioned filter wheels may comprise one or more neutral density filters as well as one or more special effect filters.

After the image-bearing radiation passes through optical low-pass filter 22 and beam splitter 18, it is focused upon image sensor 20. Image sensor 20 generates and collects the charge associated with image 12 and transfers that charge to video-processing circuitry 24 as a signal. The exact processing of the signal is dependent upon the features of the camera as desired. It should be obvious to those skilled in the art that the signal can be converted form analog to digital at various points during processing, as is necessary.

All or a portion of video-processing circuitry 24 may be emplaced within camera head 28 depending on the desired application. One application that would require the location of a greater portion of the video-processing circuitry 24 outside of the camera head would be when it is desired to have a more light-weight camera, such as a camera for on-location filming.

In the preferred embodiment, a processing unit 30 is remotely disposed from video-processing circuitry 24. Processing unit 30 is constructed using standard Euro-card personal computer boards and a rear connector panel with the signal interconnection options commonly used in broadcast studios. The signal processing carried on by video-processing circuitry 24 and processing unit 30 are further described in A High Performance Full Bandwidth HDTV Camera Applying the First 2.2 Million Pixel FT-CCD Sensor., J. Blankevoort et. al., 134th SMPTE Technical Conference, November 1992, Toronto, Canada.

The signal representative of image 12 travels from camera head 28 to processing unit 30 through a cable 36. In the preferred embodiment, cable 36 is multi-core. Cable 36 consists of one coaxial cable for a signal representative of the red portion of the image, one coaxial cable for a signal representative of the green portion of the image, one coaxial cable for a signal representative of the blue portion of the image, and one coaxial cable for the view-finder video signal, and two coaxial cables for the remaining signals, each carrying signals in one direction. Alternatively, the remaining signals can also be multiplexed into one bi-directional cable. For long-distance transmission, cable 36 would be interfaced with an optical fiber such that the signal could be transmitted over long distances without degradation in signal quality.

After processing, the signal is transmitted from processing unit 30 to a remote antenna or may be sent directly to a display. Camera head 28 can further be equipped with other features, including, for example, one or more control panels 32. Each control panel 32 is in electrical communication with video-processing circuitry 24 or processing unit 30 disposed remotely as necessary. As with video-processing circuitry 24 any portion of the control panels 32 can be located remotely. In the preferred embodiment, an operational control panel is disposed on the camera head 28, while a master control panel is disposed remotely. The operational control panel provides the control over the operational aspects of the camera, and it is arranged with user friendly directory accessible controls. The master control panel provides access to most of the set up controls via menus. Both control panels communicate electrically with video-processing circuitry 24 and processing unit 30, as necessary.

There may be provided a viewfinder 34 mounted on camera head 28. Viewfinder 34 is in electrical communication with video-processing circuitry 24 and processing unit 30. When included in the preferred embodiment, viewfinder 34 is a seven inch viewfinder provided with a magnifier (not shown) and a caller (not shown). The magnifier provides for electronic enlargement of a center of image 12 so that image 12 may fill a screen of viewfinder 34. The caller consists of lights that signify the camera selection during use.

Camera head 28 may also be used with a wide range of mechanical and optical elements, such as a variety of lenses. In the preferred embodiment, camera head 28 has an internationally standardized interface for the mounting of various lenses.

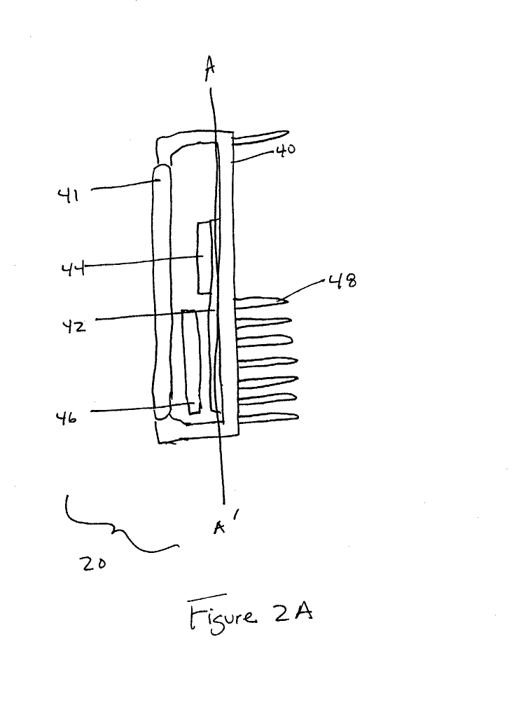

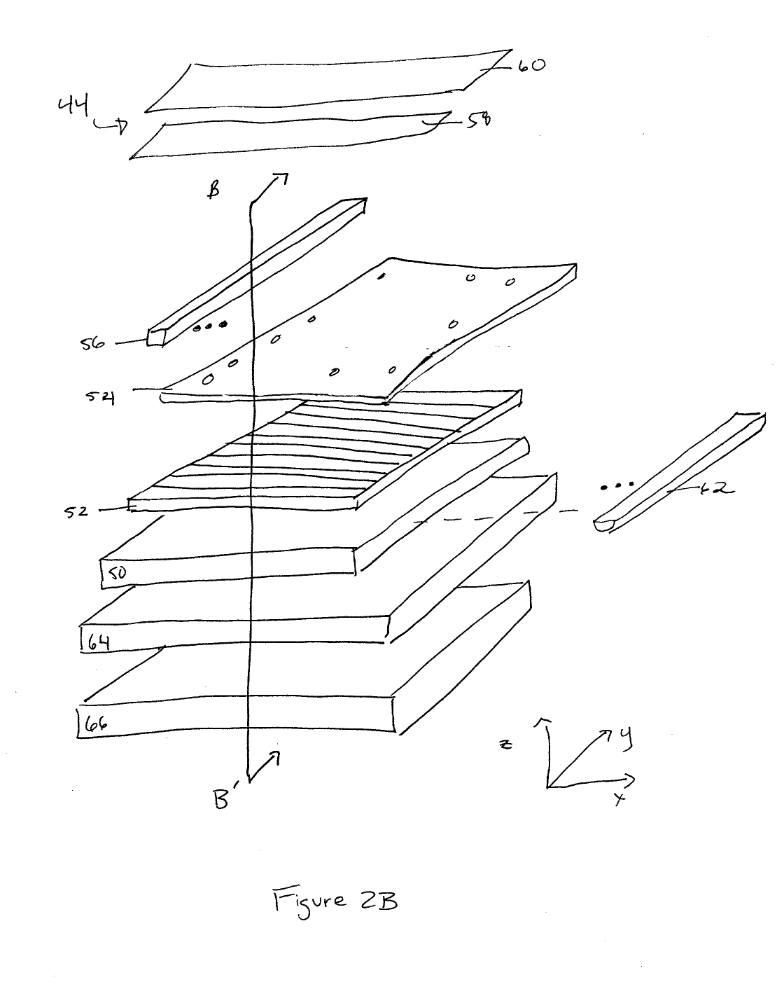

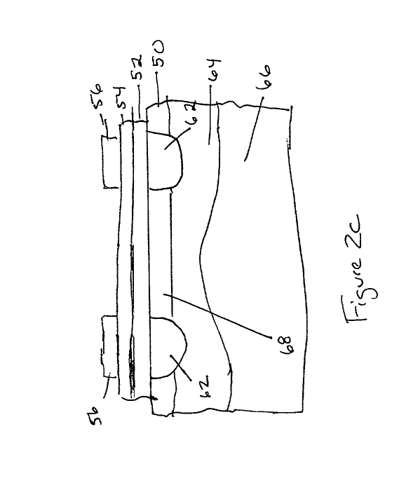

Image sensor 20 of the present embodiment is shown in a cross sectional view in FIG. 2A. In the preferred embodiment the camera contains three image sensors that are more particularly frame transfer charge coupled devices that use three phases. It should be obvious to those skilled in that art that a interline transfer type CCD charge injection device, a CMOS sensor or another similar device can be used in place of the CCD. Similarly, a two phase or four phase image sensor can be used in place of a three phase CCD or an interline transfer CCD without departing from the scope of the invention.

Image sensor 20 collects a portion of the image-bearing light as charge. The image-bearing light first passes through a cover glass 41 to a material layer 42 disposed in a housing 40. Cover glass 41 is preferably fabricated from a material that permits passage of the image-bearing light without altering the image-bearing light. A portion of image-bearing light that passes through housing 40 and impinges upon material layer 42 of image sensor 20 will photo-generate charge representative of image 12. The charge is then transferred along an axis represented by line A-A through a portion of a material layer 42, as also hereinafter described, which is then connected through pins 48 to camera 10. The charge is transmitted to camera 10 as a signal through a portion of pins 48. Pins 48 extend from the underlying surface of housing 40 and are electrically connected to the circuitry and the processing units of camera 10.

Not only is the image sensor constructed so as to effectuate charge transport, it is also constructed to collect the image-bearing light without skewing the collection. As is known in the art, a storage region of the image sensor is overlaid by a cover 46 so that the image-bearing light does not impinge upon the storage region and cause photo-generation of charge in storage region of the image sensor 20. The cover 46 prevents image-bearing light from entering material layers 42 in the storage region, such that image-bearing light passing through cover glass 41 impinges only upon material layers 42 in exposed regions.

The image-bearing light that passes through cover glass 41 will impinge upon the all remaining exposed regions of image sensor 20, not only on a radiation sensitive material 50 as shown in FIG. 2B. Portions of image sensor 20, such as an electrode 52, will pass the image-bearing light through to radiation sensitive material 50. However, other elements of image sensor 20 such as shunts 56 or other leads (not shown) will not allow the image-bearing light to pass directly through them to underlying radiation sensitive material 50. As shunts 56 and the other leads (not shown) in image sensor 20 do not absorb the light or are not translucent, they can instead cause reflection of the image-bearing light within image sensor 20. If the reflected light impinges upon radiation sensitive material 50, radiation sensitive material 50 will generate an amount of charge, a delta of charge, that is not representative of the image. At that point radiation sensitive material 50 will be generating charge not only from the image-bearing light focused upon it, but also from image-bearing light reflected from another element such as shunts 56 for example. This will result in a production of charge that is in an improper representation of the image.

To minimize this effect the other elements are preferably fabricated from a non-reflective material. The non-reflective material will absorb the image-bearing light without reflection, and therefore not contribute to improper charge generation in radiation sensitive material 50.

However, other portions of image sensor 20 are reflective such as the leads (not shown) running from shunts 56. In many conventional applications these leads are covered with a black substance that is opaque to the image-bearing light. The black substance, however, may contaminate image sensor 20. Thus, in the preferred embodiment these leads are instead covered with an anti-reflective material 44. Anti-reflective material 44 is opaque to the image-bearing light and performs the same function as the black substance of the prior art without contaminating the image sensor 20. Anti-reflective material 44 is comprised of a red filter 60 and a blue filter 58 as shown. The combination of red filter 60 and blue filter 58 produce an opaque coating that absorbs the majority of image-bearing light incident upon anti-reflective material 44, thus decreasing reflection and allowing radiation sensitive material 50 to produce charge representative of the image.

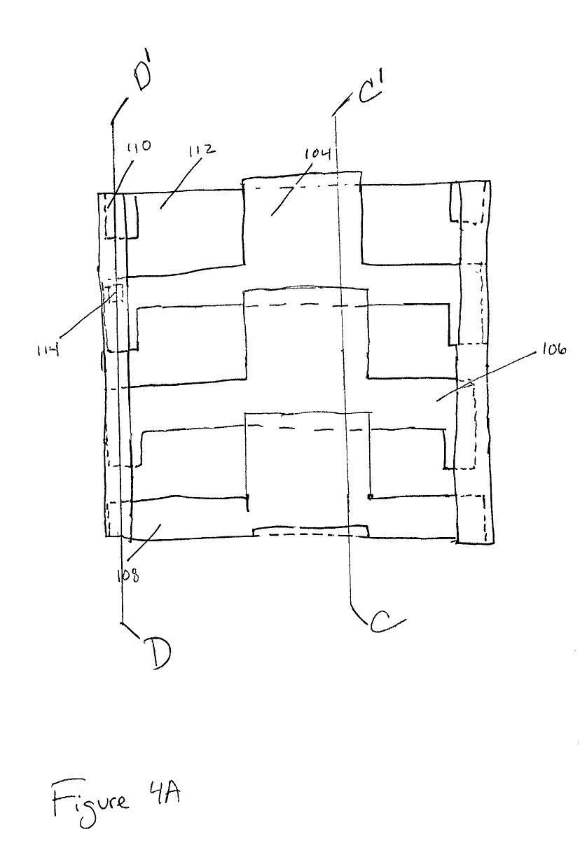

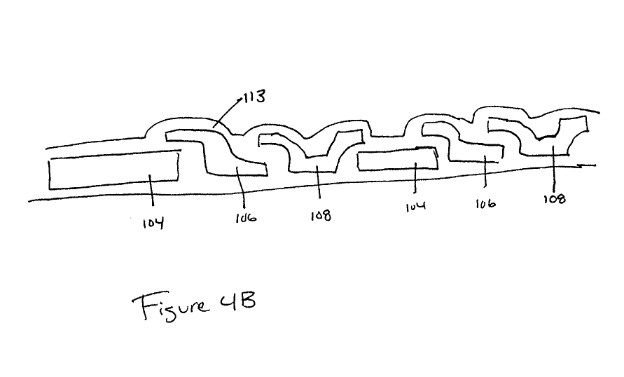

Not only is the image sensor constructed so as to decrease erroneous charge generation due to reflection, the image sensor is also constructed so as to increase the charge generation by increasing the exposure of radiation sensitive material 50 to the image-bearing light. For instance, as is shown in FIG. 2B, overlying radiation sensitive material 50 is an electrode 52. In the preferred embodiment electrode 52 is comprised of polysilicon. As polysilicon is partially transparent to the image-bearing light, the image-bearing light from the image that impinges upon the polysilicon can pass through the polysilicon to radiation sensitive material 50, and thus contribute to charge generation. Electrode 50 can be fabricated from numerous materials having adequate conductance capabilities, but that are preferably translucent to light, such as for example, indium tin oxide. As more fully described with reference to FIG. 4A the electrode includes more than one electrode arranged in a staggered pattern so as to reduce its coverage of the radiation sensitive material.

Further, shunts 56 are shown disposed over insulator 54. Insulator 54 may be fabricated from any insulating materials known in the art, such as a silicon oxide or a combination or silicon oxide and silicon nitride, for example. As shunts 56 impede the passage of the image-bearing light to radiation sensitive material 50, shunts 56 are disposed longitudinally on image sensor 20 over channel stops, hereinafter described, to minimize their coverage of radiation sensitive material 50.

Electrode 52, shunts 56 and insulator 54 also assist in charge transport in the direction of the axis A-A′. To enable the charge transport through radiation sensitive material 50, each of the electrodes 52 is selectively electrically connected to a shunt 56. Insulator 54 is interposed between shunts 56 and electrodes 52 and is selectively fabricated to allow a contact between shunt 56 and the electrodes 52 at spaced intervals. The use of insulator 54 allows shunt 56 to selectively contact electrode 52 such that charge can be transported along the A-A′ axis.

In the preferred embodiment, electrode 52 is fabricated in three layers. The three layers are disposed transversely across image sensor 20 in a spaced manner as more fully shown on FIG. 4A. The three layers of electrode 52 are electrically insulated from each other and each layer selectively contacts a shunt 56. The contact with shunts 56 charges the contacted layers of electrode 52 such that each layer of electrode 52 may independently form a separate phase φ₁ φ₂ φ₃ . . . φₙ, and provide two or more phase clocking, but preferably three phase clocking to effectuate the charge transport, as can be more fully described with reference to FIG. 4.

Image sensor 20 further comprises a substrate 66 of a first conductivity type and an overlying well layer 64 of a second conductivity type. For example, substrate 66 may be an n-type material and well layer 64 may be a p-type material. Substrate 66 may be formed of n type materials such as n doped single crystal silicon by known techniques.

In this example, radiation sensitive material 50 is of the first conductivity type and it overlies well layer 64. Radiation sensitive material 50 can be formed on well layer 64 by using any of the above mentioned techniques, including for example implantation or epitaxy techniques. Depending upon the choice of fabrication techniques, several layers can be formed at once, such as for example, well layer 64 and radiation sensitive material 50 can be formed at the same time by altering the dopant introduced into the ambient during growth under the epitaxial technique.

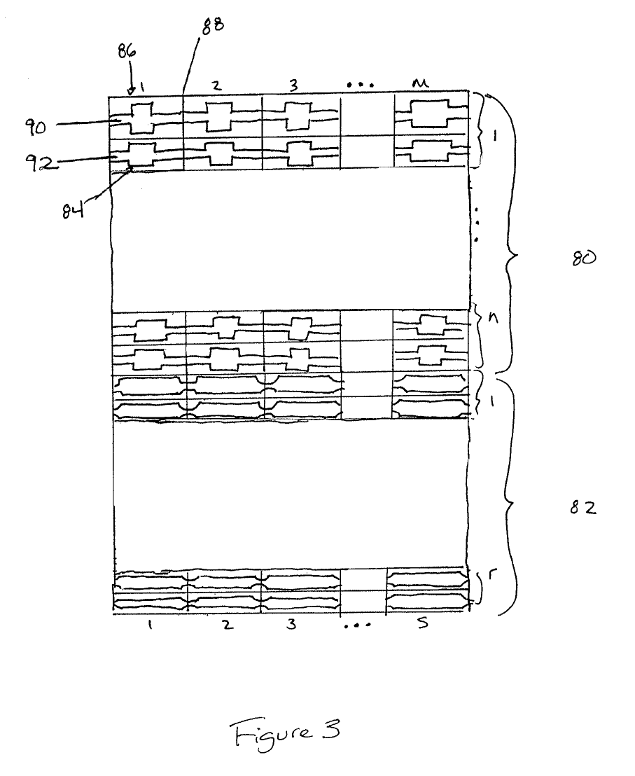

In an imaging region of image sensor 20, longitudinally spaced apart channel stops 62 are patterned to overlie and make contact at an interface with well region 64. Channel stops 62 define channels 68 therebetween as shown in FIG. 2C. In this example, channel stops 62 are of the second conductivity type p. In the preferred embodiment channel stops 62 have a graded profile from relatively heavy p+ doping near an upper surface of channel stops 62 to a relatively light p− doping near well layer 64. Doping of channel stops 62 and well layer 64 may match at their contacting interface. Electrode 52 overlies channel stops 62 and extends across in a patterned manner over image sensor 20 as further described with reference to FIG. 3.

In this embodiment substrate 66 is positively biased with respect to electrode 52, substrate 66, and electrode 52, and are positively biased with respect to channel stops 62. Given the material types and the biasing, (i.e., n-type substrate 66, p-type channel stops 62 and p-type well layer 64) there results a reverse bias semi-conductive junction or barrier between well layer 64 and substrate 66. It should be obvious to one skilled in the art that among numerous other groupings, radiation sensitive material 50 and substrate 66 could be p type, p+, or p−, while channel stops 62 and well layer 64 could be n-type or other similar variations without departing from the scope of the invention, and will form biases respectively.

Channel stops 62 are also reversed bias with respect to substrate 66 and radiation sensitive material 50. Channel stops 62 are implanted to a depth in channel 68 such that each contacts well layer 64 at its interface. Thus, when excess photo-generated charges are produced in well layer 64 or in radiation sensitive material 50 in channel 68, the reverse bias is overcome and the excess charge flows in the direction along the axis B-B′ into substrate 66. Otherwise, other generated charge remains in channel 68 along the axis A-A. The reverse bias is set so that the reverse bias forms a barrier causing barrier excess photo-generated charges flow into substrate 66, rather than flowing along channel 68 into an adjacent one of the plurality of pixels. This protection is known as antiblooming.

FIG. 3 shows a top view of an image sensor, where channels 86 are shown separated longitudinally by channel stops 88. FIG. 3 more particularly illustrates that the image sensor is divided into an imaging region 80 and a storage region 82 extending downwardly therefrom. In both imaging region 80 and storage region 82, a matrix of a plurality of pixels 84 are arranged over the image sensor. In imaging region 80, the plurality of pixels 84 form lines 1 through n and columns 1 through m. The embodiment illustrated in FIG. 3 utilizes electrodes of two phases 90 92 in imaging region 80. The electrodes of two phases 90 92 constitute one line. In the preferred embodiment imaging region 80 contains 720 pixels lines by 1280 pixels columns of square displayed pixels with an additional 16 columns and 2 lines of active pixels and 8 lines of dark pixels for reference, such that the plurality of pixels 84 creates an array of 1296 by 730, each of the plurality of pixels being 10.8 microns by 10.8 microns.

Storage region 82 extends downwardly from imaging region 80. Storage region 82 also contains a plurality of pixels arranged in a matrix of 1 through s columns and 1 through r lines. In the preferred embodiment, the columns of the storage region, s, coincide with the columns in the imaging region, m, and the lines of the storage region, r, coincide with the lines of the imaging region, n, to also form a 1296 by 730 array of the plurality of pixels, each 10.8 microns by 9.0 microns. It should also be obvious to those skilled in the art that the image sensor could be used in a non-video camera without a storage region without departing from the scope of the invention.

The plurality of pixels in storage region 82 is not constructed to increase the light exposed regions as in imaging region 80, but it is instead constructed to increase a charge storage capacity per unit area of storage region 82. As such in the preferred embodiment, the surface area of one of the plurality of pixels in storage region 82 is covered more extensively by the electrode relative to one of the plurality of pixels in imaging region 80. More particularly, the electrode selectively has an enlarged portion some of the plurality of pixels. The enlarge portion also facilitates charge transport through the storage region as described hereinafter. In the preferred embodiment, each of the plurality of pixels in the storage region is also smaller than its counterpart in the imaging region, and is 10.8 microns in the x-direction and 9 microns in the y-direction. In part, the size of each of the plurality of pixels in the storage region was dictated by specifications of conventional hardware used in cameras. Further, due to the same specifications, the lines in the storage region in the preferred embodiment are not uniform in height. It should be obvious to one skilled in the art that the dimensions of the pixels and the number of columns and lines in either the storage region or the imaging region can vary within each region or relative to one another without departing from the scope of the invention.

Turning to FIG. 4A, one of the plurality of pixels in the imaging region 80 in the preferred embodiment is shown. The plurality of pixels in the imaging region are designed such that the charge stored therein can be transferred to the storage region 82 during a blanking period when a shutter wheel blocks the image-bearing light from the plurality of pixels. A vertical transfer frequency must be sufficiently high so the charge in the imaging region can be transferred to the storage region during blanking period. To meet this task, the image sensor was designed to reduce a resistance of the electrodes. Decreasing the resistance allows the electrodes to change voltages in a shorter time, increasing the maximum vertical transfer frequency.

It should be obvious to those skilled in the art that using a shutter wheel having a different size, shape or rotation speed can increase the blanking period and allows a longer time for the vertical transfer of charge. As such, the image sensor of this embodiment can have even higher vertical transfer frequencies. The blanking period of 0.5 ms that previously allowed a 1.2 MHz vertical transfer frequency in the prior art for 589 lines, in the preferred embodiment allowed substantially at least 2.45 MHz for 730 lines.

The resistance of the electrodes in the imaging region is decreased by providing the plurality of pixels with similar optical configurations. In addition, if the electrodes in each of the plurality of pixels is positioned such that each of the plurality of pixels is not optically similar, the reproduced image will be non-uniform.

An example of the configuration in the preferred embodiment is shown in FIGS. 4A, 4B and 4C. Laying out electrodes 104, 106, 108 or the any number of electrodes and producing each of the plurality of pixels such that they are optically similar, while electrically different, will decrease the resistance and thus facilitate charge transport, while not degrading sensitivity uniformity. In the preferred embodiment, each of electrodes 104, 106, 108 has a transverse portion which extends transversely across a radiation sensitive material 112 and a channel stop region 82. FIG. 4B shows a cross-sectional view of the one of the plurality of pixels of FIG. 4A along axis C-C′, and aptly illustrates the staggered pattern of electrodes 104, 106, 108 in a pattern over more than one of the plurality of pixels.

The geometry of each of electrodes 104, 106, 108 is, in part, also similar. Each of electrodes 104, 106, 108 has a finger extending upwardly from the transverse portion, which is disposed in at least one of the plurality of pixels in a direction parallel to channel stop region 82. Each of electrodes 104, 106, 108 also has depending extensions which extend from the transverse portion of electrodes 104, 106, 108 in a direction parallel to the channel stop region and overlying a portion of the area in the channel stop region 82. Each of electrodes 104, 106, 108 could be configured without the depending extensions without deviating from the scope of the invention, as long as each of electrodes 104, 106, 108 is electrically connected to the shunts at selected contacts. Further, each of electrodes 104, 106, 108 could be configured without the fingers as long as the surface area covered by electrodes 104, 106 108 is sufficient to pass charge along radiation sensitive material 112.

Electrodes 104, 106 and 108 are also staggered from one another in a patterned matter, such that the finger extending upwardly from the transverse portion of electrodes 104, 106, 108 and the depending extensions are vertically aligned.

The periodic layout of electrodes 104, 106 and 108 not only decreases the resistance of the plurality of pixels in the imaging region, but it also increases exposed radiation sensitive material 112. The position of electrodes 104, 106, 108 depending extensions over channel stop region 110 further minimizes coverage of surface area of radiation sensitive material 112 and thus allows greater charge generation.

The layout of electrodes 104, 106, 108 in each of the plurality of pixels not only has to be similar, but electrodes 104, 106, 108 still must perform the charge transfer within the constraints set by their layout for resistance reduction. The resistance reduction is effectuated by selectively contacting at least one of electrodes 104, 106, 108 in each of the plurality of pixels to a shunt tied to a shunt. A contact 114 is made between electrode 104 and a shunt 115 that overlies channel stop region 110. Contact 114 is more aptly shown in FIG. 4C that shows a cross-sectional view of the plurality of pixels of FIG. 4A along axis D-D.

As electrode 104 extends transversely over channel stop region 110 and into more than one of the plurality of pixels, the voltage applied by contact 114 on electrode 104 will be used to transport charge of an entire group of pixels that underlie electrode 104.

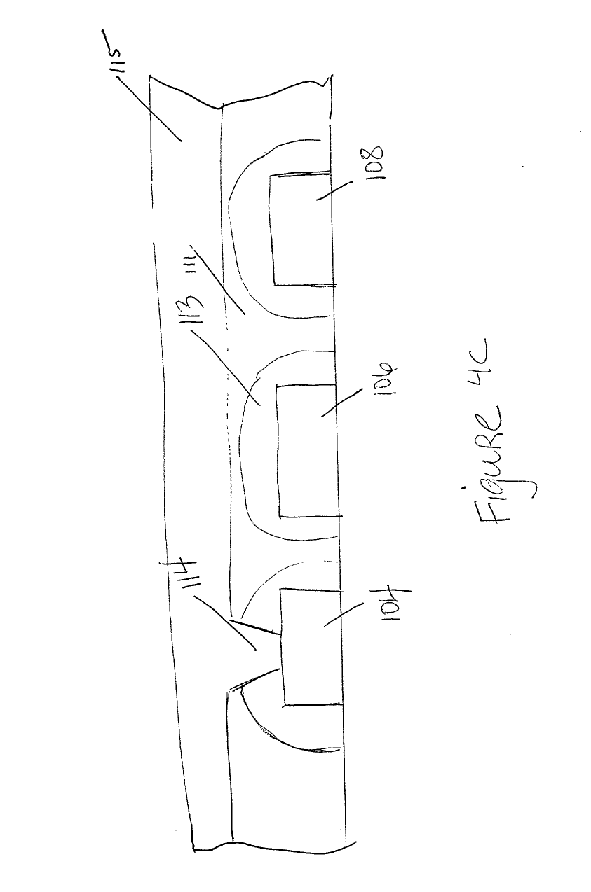

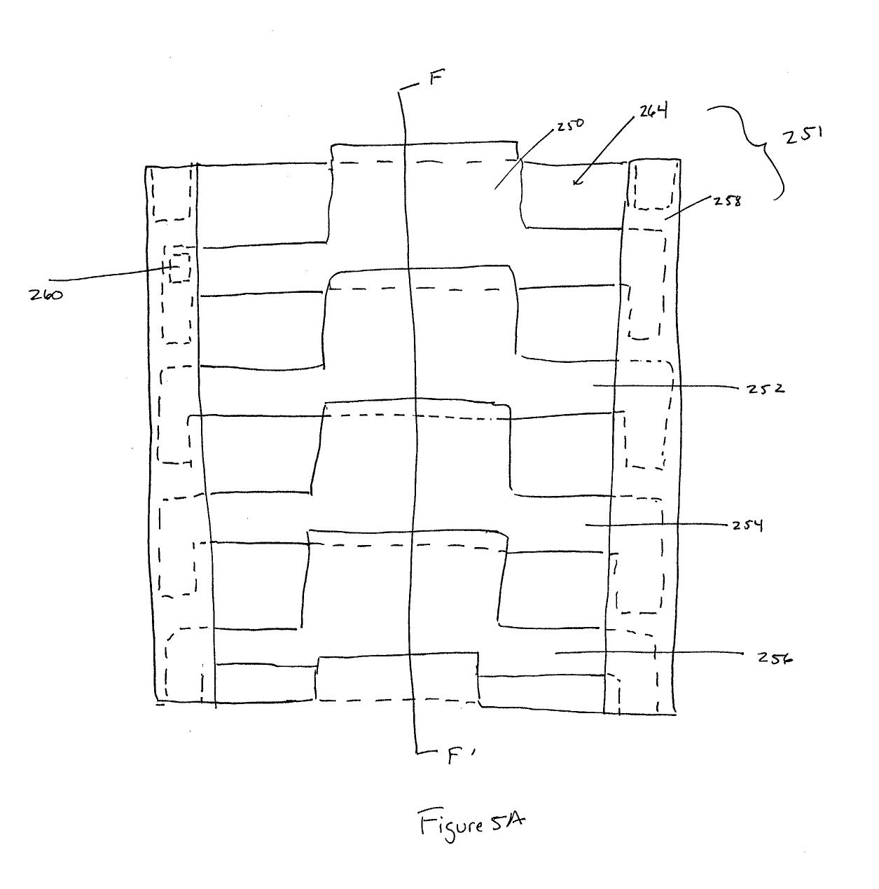

FIG. 5A shows a top view of a pixel 251 of an additional embodiment of the invention. In the configuration of this embodiment, each electrode 250, 252, 254, 256 is again disposed in staggered manner. The geometry of each electrode 250, 252, 254, 256 may again have a transverse portion which extends transversely across a radiation sensitive material 264 and a channel stop region 258. An extending finger can again extend upwardly from the transverse portion and depending extensions can extend downwardly from the transverse portion in channel stop region 258. In this embodiment, the depending extensions are completely within channel stop region 258, although the depending extensions can be extend beyond channel stop region. The geometry of the electrodes 250, 252, 254, 256 can vary as described with reference to FIG. 4A without departing from the scope of the invention.

In this embodiment, the resistances of electrodes 250, 252, 254, 256 is also decreased when the plurality of pixels comprise more than one pixel 251. FIG. 5A simply illustrates that a number of rows of electrodes 250, 252, 254, 256 that comprise one pixel has been changed, such that each of the plurality of pixels now contain four electrodes.

As it should be obvious to one skilled in the art, the imaging region could be connected to shunts to effectuate charge transport using four phases, such that only one contact is disposed within each of the plurality of pixels.

It is also possible for a pixel to have no contacts from electrode to shunt. Such a pixel would still be capable of high-speed charge transfer since a second, adjacent pixel would have a contact from electrode to shunt sufficiently close to the first pixel to be effective. This allows shunts to be wired to electrodes in groupings larger than the most basic grouping of one shunt per electrode in the pixel. For instance, if there were six shunts, these would connect the electrodes of the two three-phase pixels.

With this larger grouping of shunts, it is possible to divide them into more than one arrangement of pixels. For instance, with six shunts the electrodes would be grouped also as three two-phase pixels.

To enable pixel 251 of this embodiment to selectively contain any number of the more than one electrodes and still be optically similar to another pixel, each electrodes within each of the pixels is similar as more particularly seen in FIG. 5B which shows a cross-sectional view of pixel 251. As each electrode 250, 252, 254, 265 is similar, electrodes 250, 252, 254, 256 could comprise pixel 251 having four electrodes, but it also could comprise two pixels of two electrodes as long as electrodes 250, 252, 254, 256 selectively receive the phase voltages.

In another embodiment of the image sensor, two electrodes could have differing configurations but be disposed in a repeating pattern, thus allowing a pixel to have any number of the more than one electrodes that is a multiple of two. These electrodes may also be connected in pairs within the pixel as shown in FIG. 5B or by shunt wiring as described previously.

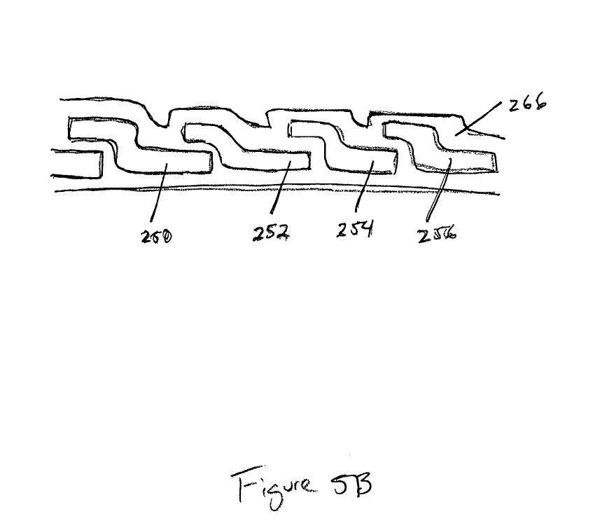

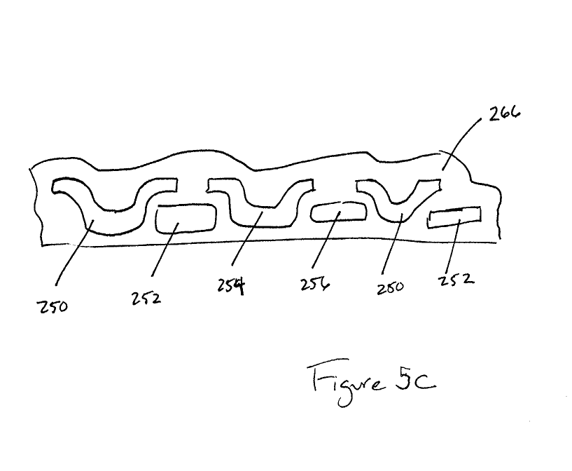

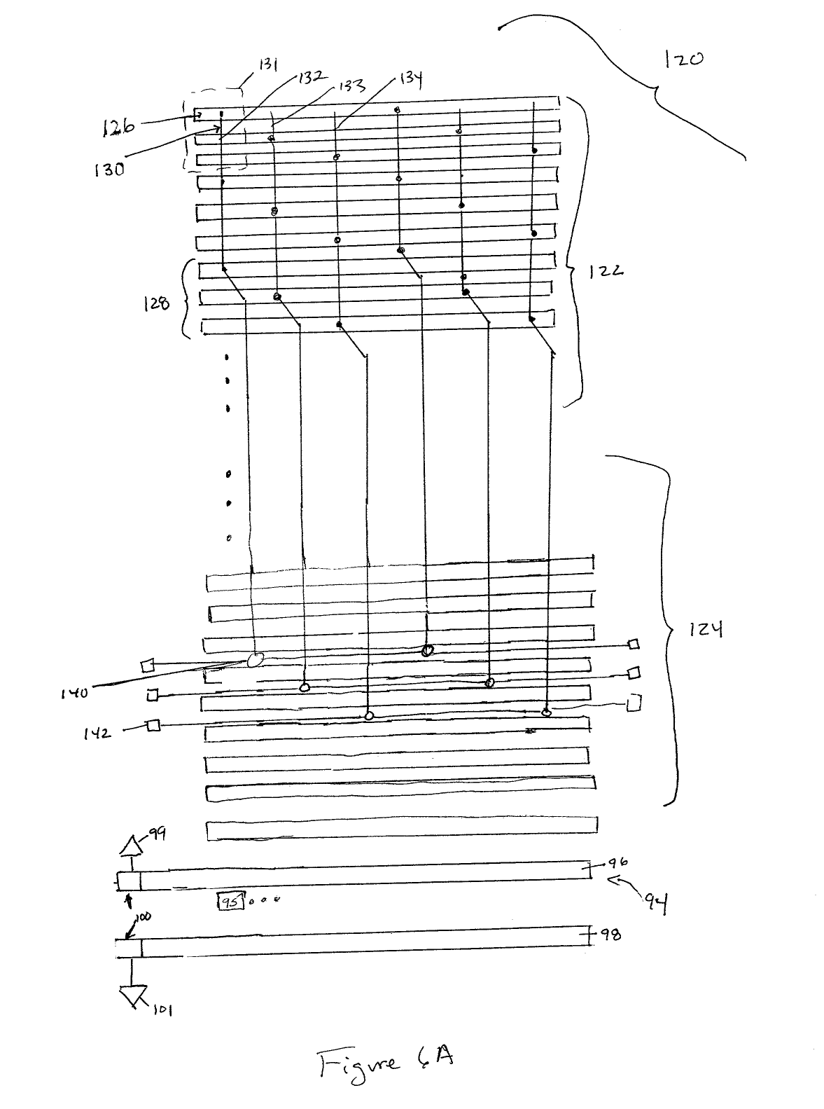

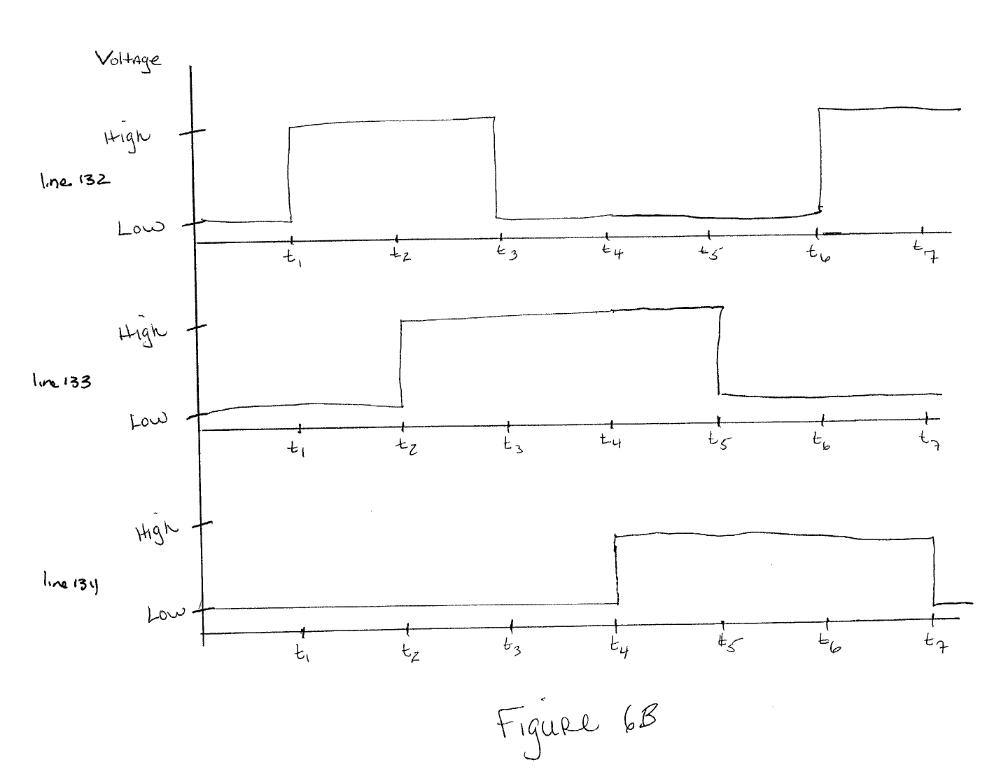

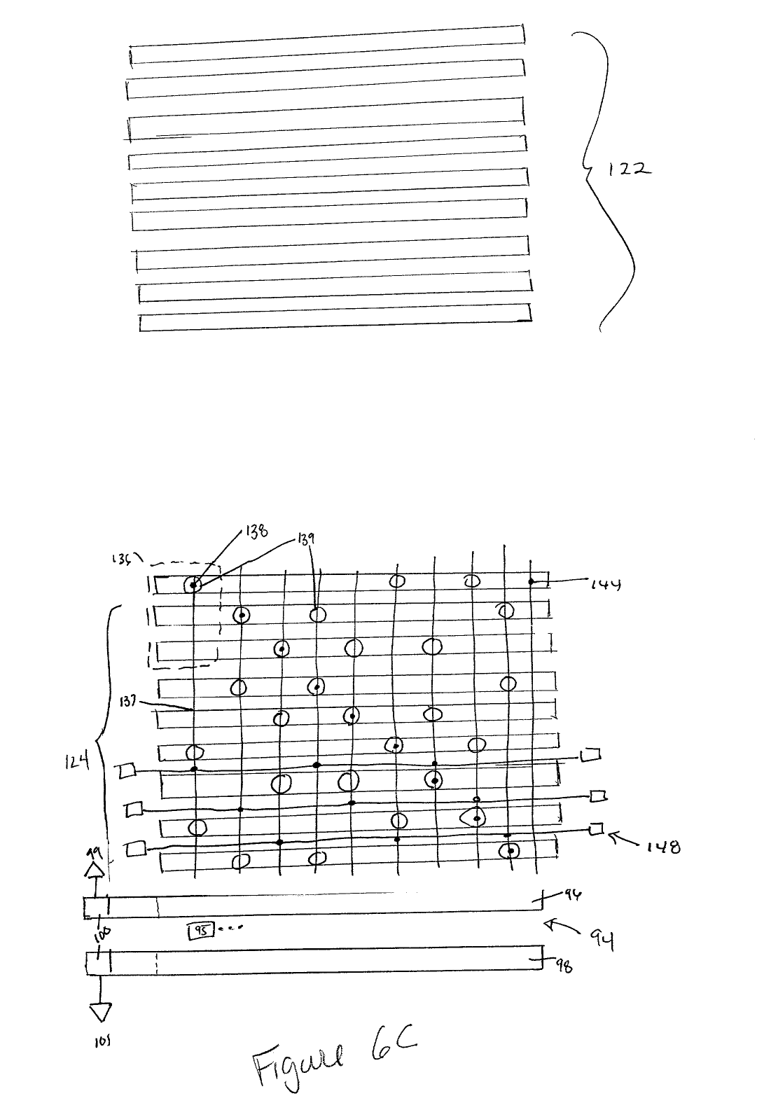

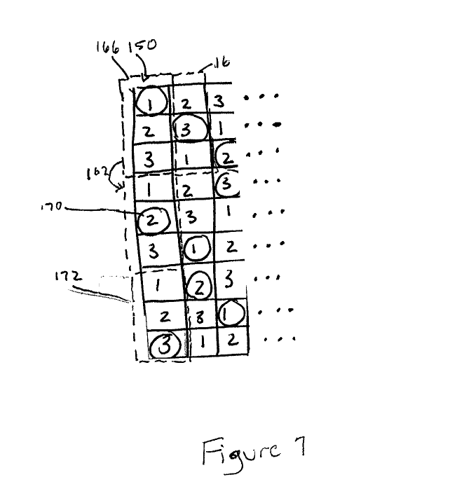

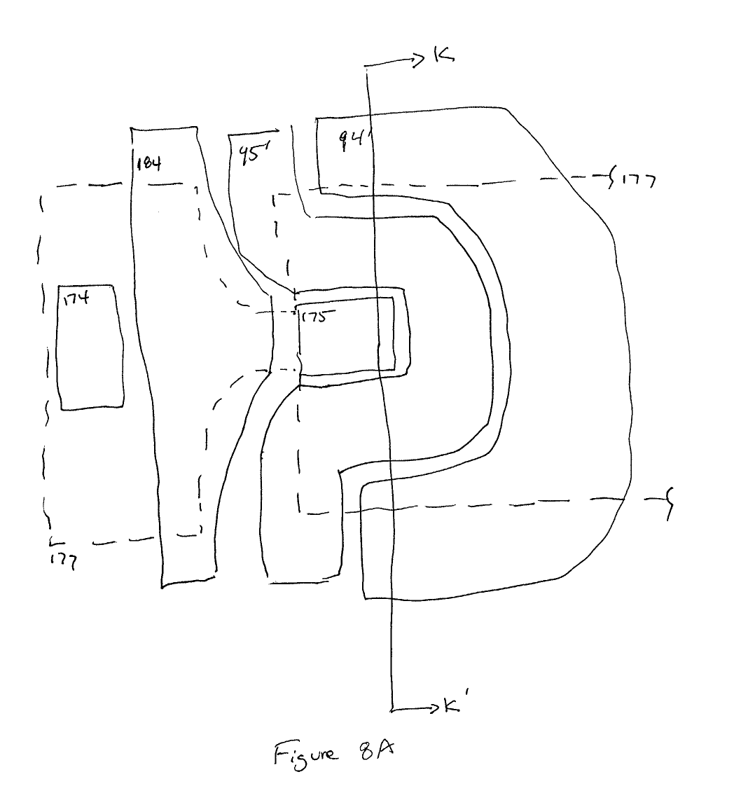

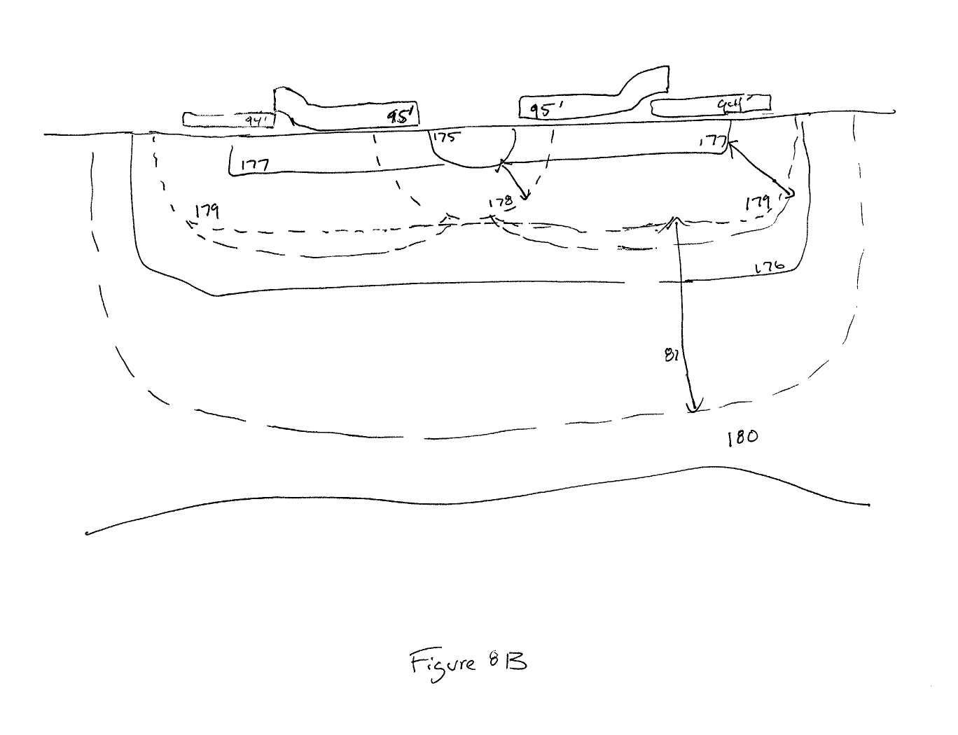

FIG. 6A is a top view of image sensor 120 that illustrates a portion of a charge transfer device disposed in the imaging region, and more particularly the interconnections of electrodes 126 disposed in rows in the imaging region. The rows of electrodes 126 in imaging region 122 can be equated to the one of the plurality of pixels shown in FIG. 4A, where first electrode 104 in FIG. 4A would be a portion of one of the rows of electrodes 126. Electrode 106 would be a portion of one of the rows of electrodes 126 disposed below the row of electrodes 126 representative of first electrode 104. The same would be true for electrode 108 shown in FIG. 4A. In other words, three rows of electrodes 126 comprise a line 128 which contains one row of the plurality of pixels. The next successive three rows of electrodes 126 again comprise the next row of the plurality of pixels and so forth down through the imaging region 122 in the preferred embodiment. Storage region 124 has the same structure although the layout of each of the plurality of pixels in the storage region differs from that of FIG. 4A.

The interconnection of electrodes 126 and shunts 130 reduce the resistance in imaging region 122. In the preferred embodiment, electrodes 126 are shunted utilizing two layers of aluminum wiring. Other electrically conductive materials can also be used as a shunt, including for example, copper, conductive polymers, ceramics. Further, shunts 130 could also be a layer of material deposited during fabrication of the image sensor and thereafter annealed, for example, or any other form of material that can be electrically connected to the electrode. In the preferred embodiment, the shunting resulted in less than a 1 ohm equivalent series resistance for the connected plurality of pixels.

To further reduce the resistance, shunts 130 are connected by buses 140 on a second layer of aluminum wiring running across storage section 124. Shunts 130 are narrow in comparison to the width of buses 140. For example, in the preferred embodiment, shunts 130 have a width of 2.3 microns and buses 140 have a width of 280 microns. Buses 140 were furthered tied to package leads 142 at each end in order to lower the series resistance of the buses 140.

As previously described with reference to FIG. 6A, shunts 130 selectively contact electrodes 126. In one embodiment, a first shunt will contact the first row of electrodes 126 and then the fourth row electrodes 126. A second shunt will contact the second row electrodes 126 and the fifth row electrodes 126 and so forth. In the preferred embodiment each shunt will contact only every third row of electrodes in the imaging region. Each electrode 126 may independently form a separate phase such as φ₁ φ₂ . . . φ_{N}, such that two-, three-, or multiple-phase clocking may be provided with electrodes 126 which are insulated from each other.

Selective activations of electrodes 126 with a phased voltage allows the charge generated in imaging region 122 to be transported vertically down the channels to storage region 124 such that each of pixels 120 in imaging region 122 is fully depleted of charge during the blanking period provided by the shuttered lens and then stored in storage region 124. It should be obvious to those skilled in the art that the radiation sensitive material in the channel also performs charge transport.

In the preferred embodiment the image sensor is a frame transfer device, and as such one example of how charge is transferred from imaging region 122 to the storage region as follows: Using a pixel 131 for example, as shown in FIG. 6B, at a time t₁ line 132 can be driven high while line 133 and line 134 are driven low. The high voltage on line 132 will cause formation of a potential energy well in the radiation sensitive region under electrode 126 to which line 132 is connected. At time t₁ the regions under electrodes 126 of line 133 and line 134 will not form a potential well. Thus, charge will be stored near the surface under electrode 126 connect to line 132 and not under the electrodes connected to line 133 and 134. At a later time t₂, line 132 remains high, line 133 is driven high and line 134 remains low. This alters the potential profile such that charge is now stored under the electrodes connected to line 132 and line 133. At this point, the contact to line 133 is not physically present in the pixel 131. However, as electrode 126 extends across pixels 120, pixel 131 will still receive the voltage from line 133. Further, since line 133 is electrically isolated from line 132 this in no way will interfere with the charge transport down the channels throughout pixels 120. Next at time t₃, line 132 can be driven low whereas line 133 and line 134 would remain unchanged, causing the charge carriers to move into the well located under the electrode connected to line 133. As such, the charge stored in pixel 131 moves from beneath a first row of electrodes 126 to beneath a second row of electrodes 126 charged by line 133. The lines cannot be driven low too quickly otherwise the charge may fall back into the potential well under the first row of electrodes. Using appropriate timing, the charge is transferred from under the first row of electrodes 126 to under the second row of electrodes 126 within pixel 131. This process is repeated again until the charge stored under electrodes 126 in electrical communication via the contact to line 133 has been moved under electrodes 126 in electrical communication with line 134. This process is repeated until the charge vertically transported down the channels from each of the plurality of pixels of the imaging region 122.

The charge 13 transferred to the storage region 124 using a similar method. FIG. 6C shows a portion of the charge transfer device in the storage region, and more particularly the interconnected shunts 144 and electrodes that assist in the charge transport in the storage region 124. The shunts 144 in the storage region 124, similar to the imaging region 122 are connected to package leads 148. Interconnections in the storage region 124, however, are not as sensitive to radiation exposure concerns, and thus can be more substantial relative to the interconnections in the imaging region 122.

After the charge is transferred down the channels of the storage region, it is transferred to transfer register 94, which in the preferred embodiment is a four phase buried channel register. Transfer register 94 includes two registers 96 98, which in the preferred embodiment, receive the charge on an even and odd column basis with the assistance of a single transfer gate 95.

For example, every other gate of transfer register 94 is in communication with a column of the storage region. At a time t₁ transfer gate 95 drives every fourth gate of the lower transfer register 98 low and every other gate on the upper transfer register 96 low. This allows the charge from every even column to enter upper transfer register 96 through the low gates, and charge from the alternate columns to enter lower transfer register 98 through the low gates. At a time t₂ the transfer gate is driven high whereby the charge held in the transfer register 94 is isolated from the influence of transfer gate 95. Thereafter the gates of the upper transfer register 96 and the gates of lower transfer register 98 are clocked out phase by phases to serially remove charge laterally out of transfer register 94. This process is repeated for each row of the plurality of pixels. Two registers 96 98 operate in parallel at one half of a pixel frequency which in the preferred embodiment is substantially 37.125 MHz. Alternatively, a clocking scheme can be used to transfer the charge in sequence or by other clocking schemes well known in the art.

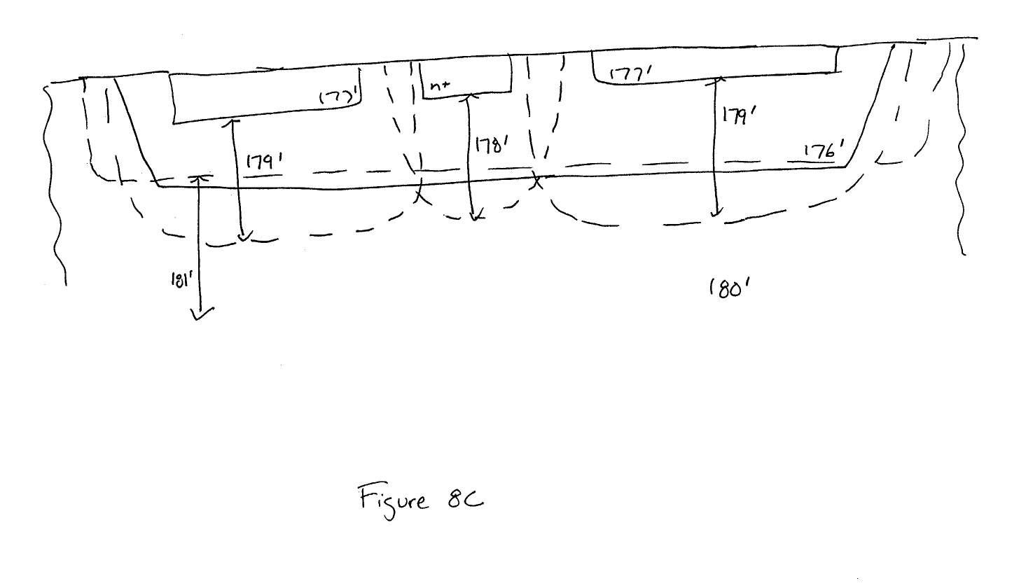

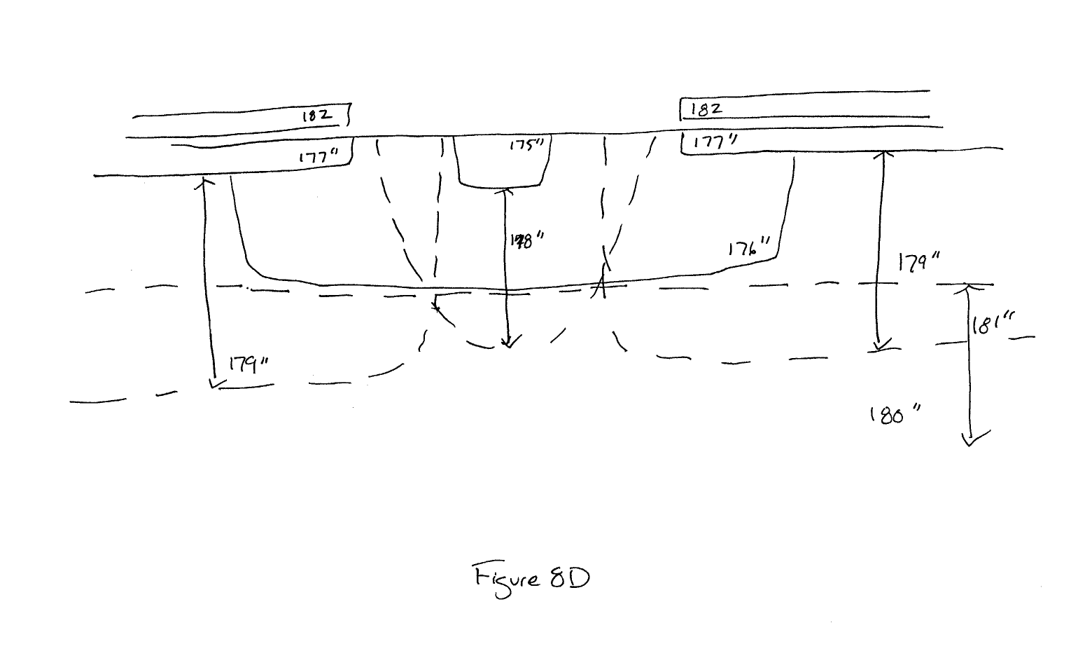

Each transfer register 96, 98 has a sense node 100 and buffer 99, 101. Sense node converts the charge to voltage as further described with reference to FIG. 8. In the preferred embodiment, buffers 99, 101 were designed to be insensitive to process variations, as hereinafter described with reference to FIG. 9D. In that embodiment, buffers 99, 101 are, however, fairly conventional three staged source-follower designs. All three drive transistors in each of buffers 99 101 are surface channel, and they produce a high transductance for low noise operations. As such, the bandwidth which is greater than 120 MHz in the preferred embodiment is high enough to ensure accurate signal transmission.

Not only does the image sensor effectuate charge transfer, it also minimizes an effect of dark current on the image. Dark current is the charge that flows between the plurality of pixels even without the presence of any image-bearing light. In an image sensor, the dark current increases as the voltage increases. As each of the more than one electrode receives an applied voltage over time also called a phase and stores the voltage, the dark current generated in the storage region is a function of a configuration of each of the more than one electrode. Similarly, as each of the more than one electrode has a geometry adapted to contact the shunt that applies the voltage and communicate that voltage to the radiation sensitive region, each of the more than one electrodes geometry also contributes to the configuration. Thus, each of the more than one electrode has a geometry, a phase, and a voltage contributing to the configuration, and the dark current generated is a function of that configuration.

As each row of the plurality of pixels is brought down one by one through the storage section before entering the transfer registers, the charge stored in each of the plurality of pixel will pick up dark current associated with the configuration of each of the more than one electrode contacting each of the plurality of pixels. For example, in one channel FIG. 6C containing pixel 136, radiation sensitive material is in contact with electrode 126 of phase one supplied by line 137. Contact 138 is made on an enlarged portion of electrode 139 as the charge transferred down the storage region is summed at transfer register 94. The resulting sum of charge would include and a charge due to the dark current caused by the contact of the radiation sensitive material with electrode 126 of the phase supplied by line 137. As such, each column would have a skewed amount of charge owing to the phase of the electrodes. This would result in an image that varies in brightness between selective columns of the plurality of pixels.

The image sensor solves this problem by electrically interconnecting the storage pixels such that the columns contain charge associated with more than one configuration of the electrodes. For example, as shown in FIG. 7 first pixel 166 containing the electrodes 1, 2 and 3 is shown. In first pixel 166, the circle around electrode number 1 indicates that the shunt contacts an electrode responsive to the first phase. In the second pixel 168, the circle around number 3 indicates that the shunt contacts an electrode responsive to the third phase and so on.

The image sensor is programmed to transfer the plurality of pixels from the imaging region into the storage region such that the charge in each channel alternates between the configurations of the more than one electrodes. Thus, the charge transported down the channel in the storage region to the transfer register will have an average of a change in charge, which can be called a delta, caused by the configuration associated with each electrode.

For example, in channel 150 the charge transferred from pixel 166 to the bottom will represent the charge collected representing the image and the dark current generated within pixel 166, pixel 170, and pixel 172 respectively. The charge will be the image plus delta 1, the charge collected from dark current caused by phase 1 of electrode 1, plus delta 2 the charge collected owing to dark current because of phase 2, and plus delta 3 the charge collected from the dark current owing to phase 3. As such, the charge transferred to the transfer registers is the charge from the image and an average of the delta 1, 2 and 3 caused by the configurations of the electrodes and as such the resulting charge collected will not reflect any bright periods and alternating dark periods owing to the extra delta collected.

In the preferred embodiment, charge is transferred through nine rows of the more than one electrodes such that each charge will encounter each configuration owing to phase and the geometry associated therewith three times. Thus, the charge that is outputted reflects an average of the charge owing to the dark current, the delta, from nine rows.

FIG. 8A shows a top view of one of the sense nodes 175 of an embodiment of this invention. The sense node 175 disposed after the terminating end of transport transfer register 94′ receives the charge passed through the channel under output gate 95′. Adjacent to sense node 175 is a reset gate 179 that is used to connect sense node 175 to a reset diode 174. Reset gate 184 restores the sense node voltage to the voltage of reset diode 174 between the signal change for subsequent pixels.

The sense nodes 175 change the charge into voltage. Voltage is determined according to the relationship V=Q/C, where V=voltage, Q=charge, and C=the capacitance of the sense node. The charge (Q) in this equation is equal to the amount of charge generated from the image-bearing light.

Each of the sense nodes consists of a n+ doped region forming a junction to the a p-well. In a conventional sense node, the junction normally has a capacitance between the n+ doped region and the p-well in the conductive region. The capacitance depends on an area covered by the junction and a width of a depletion region, where depletion region is a region where majority carriers are swept away by an applied voltage. The capacitance can be reduced by reducing the area covered by the junction or increasing the width of the depletion region, but it is not normally eliminated.

To obtain a maximum possible signal voltage, so as to raise the signal much higher than the noise of the three-stage source follower buffer, it is necessary to minimize the capacitance of the sense node as much as possible. A portion of the capacitance of the sense node 175 is between the conductive portions of the n+ doped region and the p-well. For proper operation of the sense node 175 the n+ doped region cannot be fully depleted, therefore this embodiment depletes the p-well. Each of the sense nodes of one embodiment of this invention, utilizes a combination of dopants and electrodes to fully deplete the p-well on all sides of the sense node for a great enough distance to substantially reduce or even eliminate capacitance between the sense node and the p-well. Not only does this reduce this capacitance of the sense node, but it also minimizes if not eliminating coupling of noise from the p-well to each of the sense nodes.

FIG. 8B shows a cross sectional view of the sense node 175. The sense node 175 is formed by the n+ region. Using an n− layer 180 underlying a p-well 176, the depleted region 178 is formed. In the depletion region there are minimal or no charge carriers, which makes the depletion region minimally or non-conductive. A minimal or non-conductive region has a small or zero capacitance. The depletion region 178 is enhanced by disposing n-buried channels 177 adjacent the n+region which also have a depletion region 179. The n-buried channels 177 junction at the p-well 176 in combination with the n-layer 180 forms a p-well, n-layer depletion region. If the n-buried channels 177 have little or no charge carriers in them, the p-well 176 for the entire area surrounding the n+ doped region, the sense node 175 will be depleted. In this embodiment, the state of n-buried channels to ensure that no or small amounts of charge carriers are present and are drained onto the n-layer 180, is ensured by the electrodes including the reset diode 174, the reset gate 184, and output gate 95′ that is a last gate of the transfer register 94′.

The n-buried channel 177 as shown on FIG. 8A and FIG. 8B can vary as long as the electrodes 94′, 95′, 184 covered a majority of the n-buried channel 177 to ensure charge will not be present in the n-buried channel 177.

Another embodiment of the sense nodes 175 is shown in FIG. 8C. In this embodiment the n+ region again forms a depletion region 178′. But in this embodiment the n-buried channel 177′ is spaced apart from the n+ region. A depletion region 179′ that has been arbitrarily moved away from the n+ region 175′ forms between the n-buried channel 177′ and the p-well 176′. The depletion region 179′ can be moved even further. The only limit is that they cannot be moved so close together so the n-buried channel contacts the sense node 175 or so far away that some of a portion of the p-well near the sense node 175 is not depleted.

In FIG. 8D, the n+ doped region 175″ again forms a depleted region 178″. The n-buried channels 177″ form a depleted region 179″, and the p-well 176″ and the n-layer 180″ form a depletion region 181″. In this embodiment however the n-buried channels 177″ drain directly into the n-layer 180″ horizontally instead of vertically through the p-well 176″. In this embodiment, electrodes 182 do not cover the entire n-buried channels 177″, but sufficiently deplete them of charge carriers. If the n-buried channels 177″ are near the n+doped region 175″ and the p-well 176″ will be fully depleted of all charge carriers and have a negligible capacitance.

Various spacings of the regions and other combinations of electrode biasing and dopants can also deplete the p-well 176′ without departing from the scope of the invention. For example, n+ implants can also be used to deplete the p-well 176′.

The sense node amplifies the signal representative of the image prior to transmission of the signal to the buffer circuitry which introduces a majority of any noise into the signal. As such, the signal is amplified without a corresponding amplification of the noise. Increasing the voltage even further by the depleted p-well further decrease a signal-to-noise ratio of the camera.

Turning now to FIG. 9A, FIG. 9A is a top view of the buffers 99, 101 illustrated on FIG. 6C, and will be described with reference to FIG. 6C. After the voltage is amplified in the sense node 100, the resulting signal is transmitted to the buffers 99, 101. Buffers 99, 101 having a low impedance are able to supply greatly decreased current while maintaining the voltage of the signal, enabling the signal to be transmitted to subsequent circuitry in the camera external to the one or more image sensors with minimal degradation. In the preferred embodiment, buffers 99, 101 have identical performance to avoid adding column-oriented fixed-pattern noise to the signal.

In image sensor of FIG. 6C, buffers 99, 101 had to be disposed alternately above and below transfer registers 96, 98 owing to space constraints caused by the close proximity of transfer registers 96, 98. It should be obvious to those skilled in the art that the using even a slightly different configuration for transfer register 96, 98, buffers without the constraints described below can be used.

As buffers 99, 101 of this embodiment are disposed above and below transfer registers 96, 98 respectively, to perform similar functions with respect to transfer registers 96, 98, buffers 99, 101 to have a mirror-imaged design. As such, a lower buffer 101 is an inverted copy of an upper buffer 99, flipped top to bottom. FIG. 9D illustrates a top view of the mirror-image design of buffers 99, 101 for one embodiment of this invention.

As buffers 99, 101 comprise transistors formed using several different photolithography steps, it is possible that misalignment can occur between the various lithographic steps. Misalignment results in causing geometries on a layer of the transistor to shift with respect to another. A shift can change characteristics of the transistors and accordingly affect the performance of the buffers 99, 101, including changes in gain, offset, or capacitance. For example, as the two buffers 99, 101 are mirror images, if one layer shifts upwards on one buffer relative to a corresponding layer on a second buffer, the gain of the one buffer may increase while lowering the gain of the second buffer.

An effect of the shift in layers is more particularly shown with reference to FIG. 9A that illustrates a transistor. The transistor is formed from geometries of several photolithographic layers and is surrounded by a channel stop 220 that creates an isolation ring surrounding the transistor. The transistor has a transistor gate 222 preferably of polysilicon. A source 228 and a drain 230 are formed in upper and lower regions, respectively, overlies the entire structure, where the upper and lower regions are not covered by the transistor gate 222. An insulating layer 223 overlies the n+ implanted layer 224, a portion of the insulating layer 223 defines holes 226. The holes allow selective connection to elements of the transistor.

FIG. 9B shows a cross-sectional view of the transistor of FIG. 9A through line A-A′. As shown in FIG. 9B, the relative locations of the photolithographic layers to each other affect the performance of the transistor. For example, a different spacing between holes 226 and transistor gate 222 can result in a different resistance 225 in source 228 or drain 230 regions of n+implanted layer 224.

The relative locations of transistor gate 222 and channel stop 220 also affect the performance of the transistor as shown in FIG. 9C, where FIG. 9C illustrates a cross-sectional view of the transistor of FIG. 9A through line B-B′. As is more clearly shown in FIG. 9C, an amount of overlap between transistor gate 222 and channel stop 220 is directly related to a capacitance 221 between these two elements and thus affects the performance of the transistor.

As it is critical that buffers 99, 101 have substantial identical behavior with respect to each other in this embodiment despite misalignments, buffers 99, 101 are designed so changes caused by misalignment affect each of buffers 99, 101 in the same manner.

FIG. 9D shows part of buffer 99 and part of buffer 101 in this embodiment. One transistor is shown for each of buffers 99, 101 in a mirror-imaged orientation. Each transistor is arranged having a transistor gate 232 running vertically, with a source 234 on the left of the transistor gate 232 for each of the buffers 99 101 and a drain 236 on the right of the transistor gate 232 for each of the buffers 99, 101.

As such, misalignment of contacts 238 will affect both transistors in the same manner. If, for example, the transistor gate 232 moves slightly to the left relative to the contacts 238, both transistors have increased drain resistance and decreased source resistance. Further, if the transistor gate 232 moves up or down, the source or drain resistance on both transistors will not change. Any rotational misalignment of the transistor gate 232 that are permitted during fabrication are too small to cause noticeable effects between the two buffers 99, 101 because the buffers 99, 101 are disposed near each other. Thus, any relative displacement of the transistor gate and the contacts will not change the performance of one transistor in relation to the other.

Also, if the transistor gate 232 shifts slightly upwards compared to the channel stop 240, the overlap of the top end of the transistor gate increases, while the overlap of the bottom end decreases by the same amount. Thus the total amount of overlap remains constant. Shifts of the transistor gate to the left of the right have no impact on the overlap.

As the overlapping of the transistor gate 232 with a channel stop 240 is provided at both a top end and a bottom end of each transistor gate 232, the capacitance owing to the overlap will remain substantially constant and substantially equal for each of the buffers 99, 101. The capacitance of the overlap adds to the capacitance of the sense nodes 100, and thus any mismatch that might have occurred using the transistor of FIG. 9A would have a significant impact on image noise.

This embodiment illustrates that designing parts of a circuit such that shifts in geometry location relative to geometries of different layers do not cause performance mismatches when used with two elements of a mirror-image design. It should be obvious to one skilled in the art that circuits that are insensitive to misalignments can be used for other applications, including for example audio signal processing of other applications where behavior of the buffers needs to be substantially identical without departing from the scope of the invention.

The output from buffers 99, 101 is then delivered appropriately using a delay line principle such that the output signals are combined in a video pre-processor of the camera at the appropriate time.

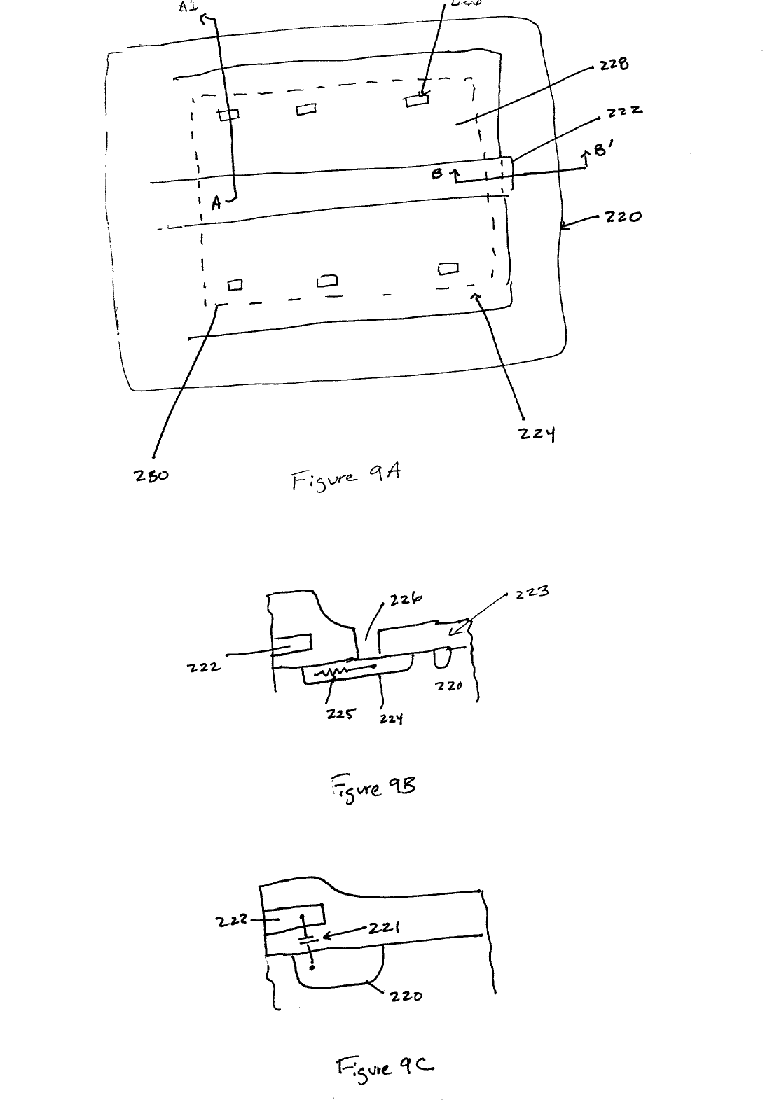

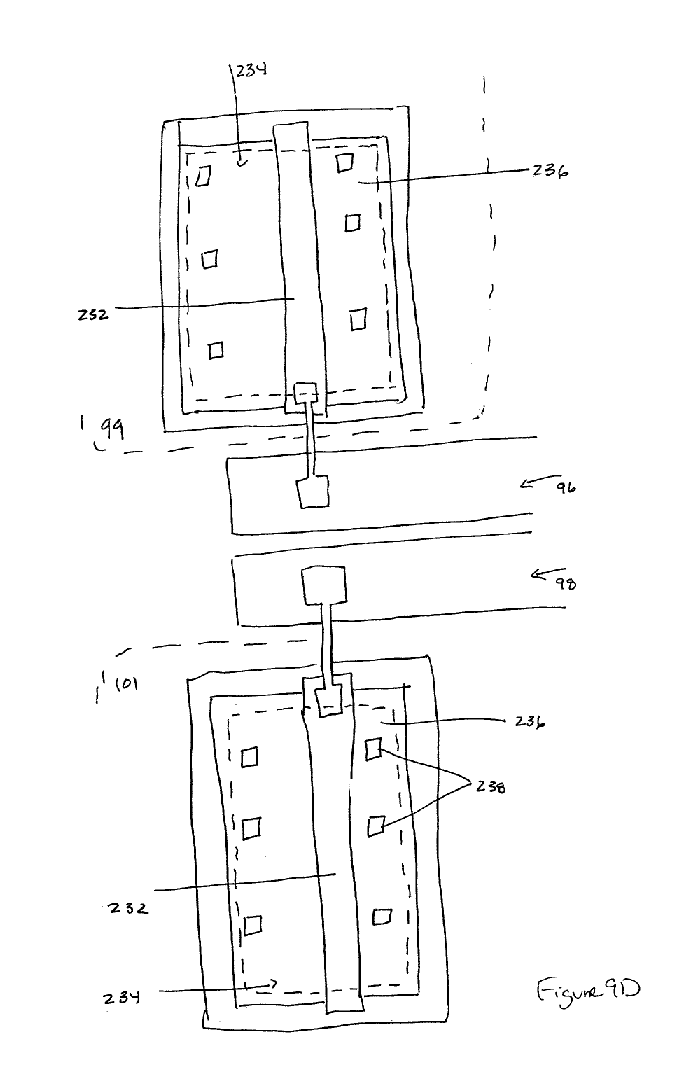

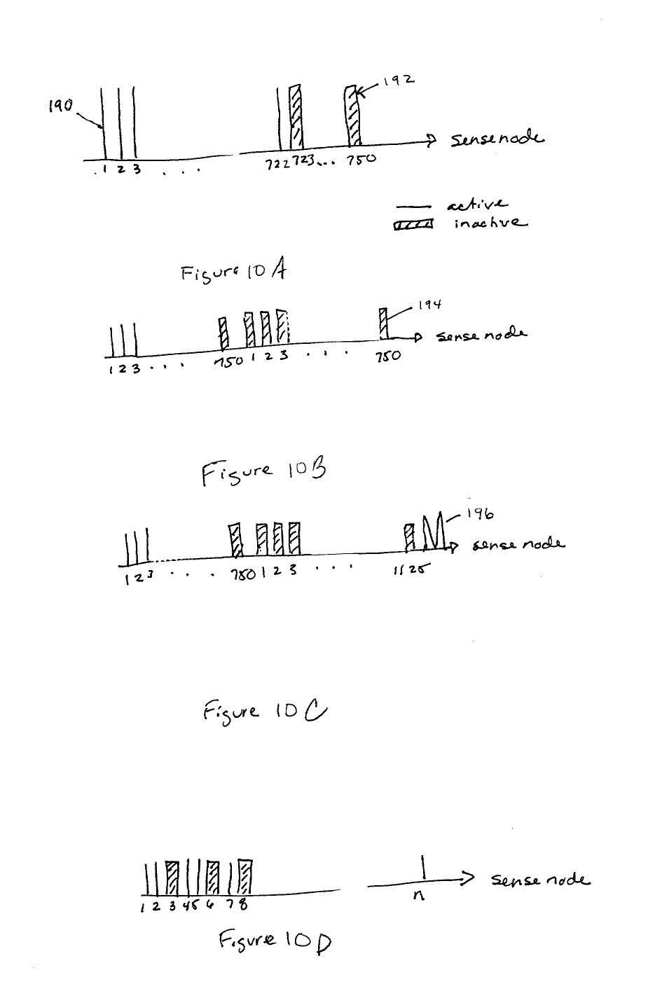

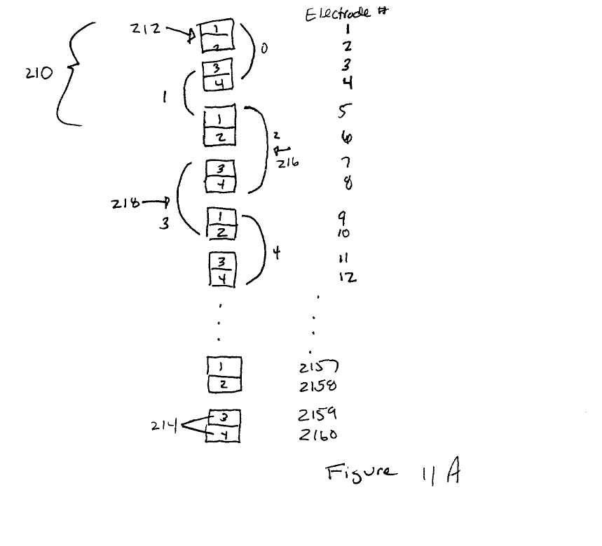

Turning now to FIG. 10A, the camera can further manipulate the signal by varying a frame transfer rate of the output as shown in FIGS. 10A, 10B, 10C and 10D. The camera of this embodiment can produce effects without post-processing such as slow motion and fast motion. The camera can also produce images of different formats, such as supplying an image to a view finder that requires less resolution than other reproduced images, or other applications in the industry.

To vary the frame rate, a number of line intervals for each frame in a output signal are varied, while other parameters are kept constant such as a pixel frequency, where pixel frequency is the number of pixels read out per second, and a line time, where line time is the number of lines read out per second.

FIG. 10A shows a reference frame rate of the camera in the preferred embodiment. The line time of the camera is derived by multiplying the frame rate by a number of line intervals 192. In the preferred embodiment, the number of line intervals 192 is 750, and the frame rate is 60 frames per second. Thus the line time is 45×10³ lines per second.

As the camera functions in a progressive-scan mode the 750 lines intervals constitute one frame. The line intervals are adapted to receive both active lines and inactive lines. In the preferred embodiment, 722 of these lines are active while 8 are used for dark pixel reference purposes and 20 are inactive lines during which the charge is transferred to the storage region.

To vary the frame rate, the camera increases the number of line intervals 192 per frame. FIG. 10B illustrates the camera functioning at a varied frame rate of 30 frames per second which is equivalent to an interlace-scan application. If the embodiment of FIG. 10B was recording the same scene as FIG. 10A, the signals representative of that same image contained in lines 1-750 of FIG. 10A would coincide with lines 1-750 of FIG. 10B. Instead of being followed by another set of 750 lines, as in FIG. 10A however, a second 750 set of lines that are inactive are included within each frame of the embodiment of FIG. 10B. Thus, one frame will consist of double the lines, or double the line intervals of the FIG. 10A. Thus, FIG. 10B has 1500 line intervals, at the same line time of 45×10³ lines per second, and therefore functions at 30 frames per second.

The set of additional lines added to increase the line intervals are inactive 194. In this example, FIG. 10A contains 28 inactive lines and FIG. 10B contains 750 plus 28 inactive lines for a total of 778 inactive lines.

FIG. 10C illustrates still another embodiment of the camera producing 24 frames per second, which is the typical frame rate required for a movie camera. In this application even more line intervals containing inactive lines were required than in the 30 frames per second example of FIG. 10B. 24 frames per second is achieved using 1875 line intervals containing the lines 1-750 of FIG. 10A followed by 1125 inactive lines. It should be obvious to those skilled in the art that the camera can operate in any varying frame rate limited only by the ability of the camera to clock out the lines in the time required. In addition the frame rate could be varied by reducing the number of line intervals per each frame.

An entire video can be at one frame rate or the camera can change the frame rate continuously during image-bearing light collection. As such, the devices receiving the signal from the camera can be informed what the frame rate is during one session. One such method, for example, is to provide a trigger pulse 196 to denote the end or the beginning of a new frame. It should be obvious to those skilled in the art that other methods of informing the components of the variable frame rate can be used without departing from the scope of this invention.

The frame rate can also be varied to meet user qualifications and is not limited necessarily to the standards currently used in the industry. FIG. 10D illustrates one such example whereby the frame rate is varied to the user's qualifications. In this example, the active lines 1, 2, 4, 5 and 7 and N are dispersed in the frame with the inactive lines 3, 6, 8. The line intervals would equal the number of active lines and inactive lines in each frame, where the line intervals are chosen based on a user desired frame rate. This method is aptly suited for slight modifications to one of the standard frame rates, but it can also produce the standard rates using alternating smaller groups of one or more lines that are inactive followed by one or more lines that are active, in contrast to the larger groups as shown in FIG. 10B.

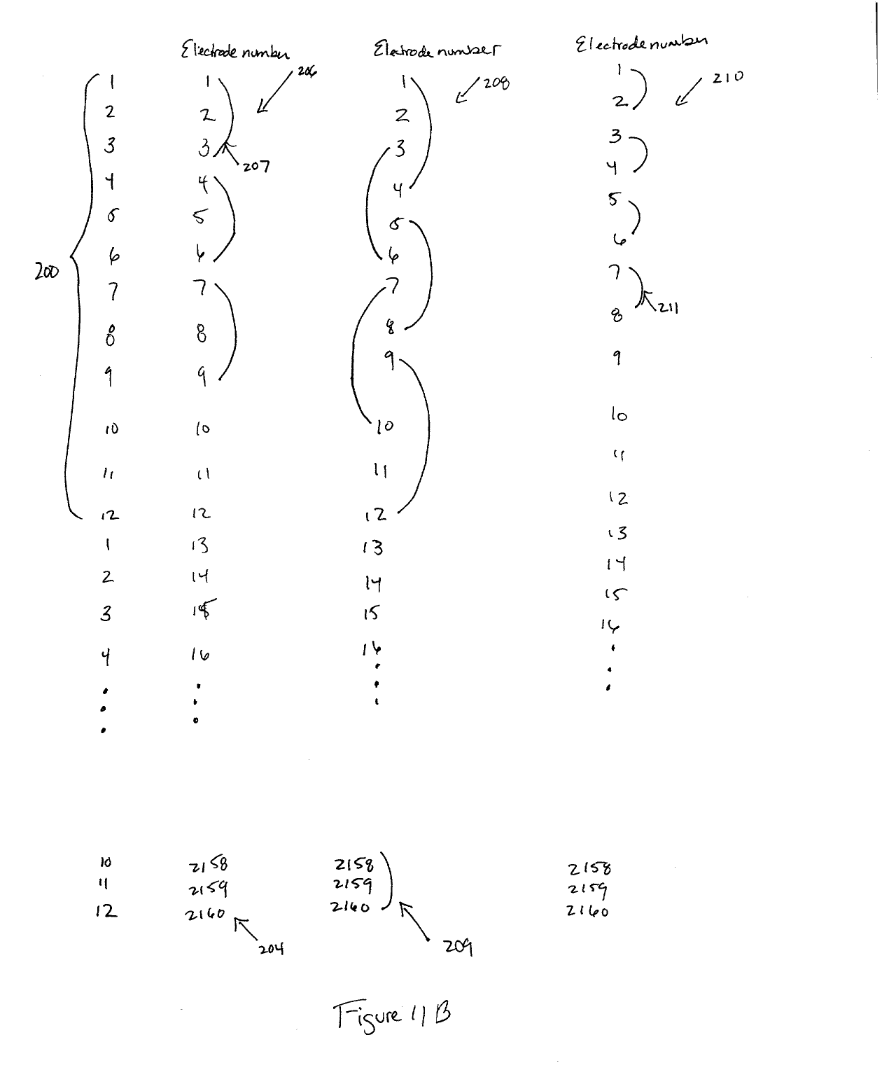

FIG. 11A shows a simplified version of how interlace-scan camera 210 connects electrodes to achieve interlace scanning. The interlace-scan camera with 540 rows of the plurality of pixels having four electrodes 214 in each will therefore have a column 212 of 2160 electrodes. To produce an interlace picture, an interlace-scan camera 210 reads out two fields of the electrodes 214 being an even field 216 consisting of even numbered lines and an odd field 218, consisting of odd numbered lines.

The even field 216 constitutes groups of electrodes 214 such as 1-4, and 4; and then 5-9 and so on until electrodes 2157-2160. The even field 216 constitutes 540 groups of four electrodes 214 each.

The odd field 218 constitutes groupings of electrodes 214 such as 3-6; and then electrodes 7-10 and so on, so that the odd field 218 constitutes 540 groups of four electrodes 214 each.

The even field 216 contains half of a picture element while the odd field 218 contains the other half of the picture element. The even field 216 and the odd field 218 are added together to produce one frame. The use of the even field 216 and the odd field 218 enables the interlace-scan camera 210 to output a picture containing all the information of one frame however it does sacrifice resolution by summing the even field 216 and the odd field 218.

The image sensor of the preferred embodiment reads in the progressive-scan mode, reading all of the lines of electrodes at once. The image sensor includes 720 lines each containing three electrodes for a total of 2,160 electrodes. However, the image sensor is capable of switching between the progressive-scan mode and the interlace-scan mode by manipulating the connections of the electrodes prior to readout.

FIG. 11B illustrates an example of one method to connect the electrodes in the switchable image sensor of one embodiment. In this example, the electrodes are connected in sets of twelve signals 200, where the signals are clock signals. Electrodes 1, 13, 25 and so on are tied together. When wired as twelve signals, the electrodes 204 can support 2, 3, and 4 phase operation because 12 is a common multiple of each. For three phase operation 206, a switchable image sensor connects the 2,160 electrodes 204 either into groups of three for 720 line progressive for four phase 208 into groups of four for 1080 line interlace or for two phase 210 groups of two for the 1080 line progressive as shown on FIG. 8B.

An external control could further interconnect the set of twelve signals. For example, for three phase operation 206, signals 1, 4, 7, 10 form phase 1, signals 2, 5, 8, 10 form phase 2, and signals 3, 6, 9, 11 form phase 3 that would be interconnected to constitute 720 lines 207.

For four phase operation 208, signals 1, 5, 9 form phase 1, signals 2, 6, 10 form phase 2, signals 3, 7, 11 form phase 3, and signals 4, 8, 12 form phase 4 that would be interconnected to constitute 1080 lines 209. Switching between these groups enables operation in either progressive-scan or interlace scan mode.

For two phase operation 210, signals 1, 3, 5, 7, 9, 11 form phase 1 and signals 2, 4, 6, 8, 10 form phase 2 that would be interconnected to constitute 1080 lines 211.

Switching between 1080 interlace (4 phase 208), 720 progressive (3 phase 206), and 1080 progressive (2 phase 210) is accomplished by combining the twelve signals in different manners to make the various phase arrangements. It should be obvious to one skilled in the art that the combinations can be made with switches or in many other manners well known in the art.

While there has been described what at present are considered to be the preferred embodiments of the present invention it will be apparent to those skilled in the art that various changes and modifications may be made therein without departing from the invention and it is intended in the accompanying claims to cover all such changes and modifications as forward in the true spirit and scope of the invention.

What is claimed is:

1. A camera for capturing images conveyed in image-bearing light, said camera comprising:
a light-proof enclosure having an aperture with a shuttered lens through which the image-bearing light is focused; and
at least one image sensor disposed within said light-proof enclosure, said image sensor in optical communication with the image-bearing light, said image sensor comprising an imaging region comprising a two-dimensional array of optically-similar pixels, each said pixel adapted to receive at least a portion of the image-bearing light and to transfer a corresponding charge signal therefrom,
said image sensor further comprising at least one electrode disposed across said imaging region in a first direction, and charge transfer means disposed across said imaging region in a direction perpendicular to said first direction, wherein charge transfer occurs in said second direction.

2. The camera according to claim 1 wherein said camera is a progressive-scan camera and said image sensor is solid-state.

3. The camera according to claim 1 wherein the maximum frame rate is at least sixty frames per second.

4. The camera according to claim 1 further comprising a shutter wheel adapted to provide a blanking period of at most about 0.5 ms.

5. The camera according to claim 1 wherein the high resolution is defined by an image format of at least 720 pixels by 1280 pixels.

6. The camera according to claim 1 wherein said image sensor further comprises a storage region for storing the charge in electrical communication with said charge transfer means and adapted to receive the charge transported from the imaging region by means of said charge transfer means.

7. The camera according to claim 6 wherein the charge transfer means further comprises:
at least one electrode disposed in the imaging region; and
at least one shunt overlying said plurality of pixels, said shunt being in selective electrical communication with said electrode.

8. The camera according to claim 7 wherein said shunt is disposed upon said imaging region so as to minimize coverage of said pixel.

9. The camera according to claim 7 further comprising at least one bus disposed in said storage region, wherein said shunt is electrically connected to said bus so as to reduce the electrical resistance of said electrodes.

10. The camera according to claim 9 wherein said shunt is narrow in comparison to said bus.

11. The camera according to claim 7 wherein each said electrode is in selective electrical communication with at least one pixel, and said electrode is responsive to a predefined applied voltage to transfer the charge from said pixel.

12. The camera according to claim 11 wherein said electrodes are staggered relative to each other.

13. The camera according to claim 7 wherein each said electrode comprises a transverse portion which extends across said imaging region, and an extension which extend from said transverse portion to contact at least one said shunt.

14. The camera according to claim 7 wherein said plurality of pixels further comprises a radiation sensitive region, said electrode covering less than all the entire radiation sensitive region.

15. The camera according to claim 6 wherein the charge transfer means transfers the charge at substantially 1.3 MHz.

16. The camera according to claim 6 further comprising anti-reflective means for decreasing internal reflection of the image-bearing light.

17. The camera according to claim 16 wherein said anti-reflective means comprises a plurality of filters to absorb substantially all incident optical radiation.

18. The camera according to claim 17 wherein said plurality of filters comprises a red filter and a blue filter.

19. The camera according to claim 6 wherein said image sensor further comprises:
at least one sense node adapted to translate the charge into an electrical signal having a voltage; and
a depleted p-well disposed in electrical communication with said sense node, said depleted p-well adapted to reduce the capacitance of said sense node whereby the voltage of the electrical signal is increased and a signal-to-noise ratio of the camera is increased.

20. The camera according to claim 19 wherein said image sensor further comprises a transfer register in communication with said storage region, said transfer register comprising an end terminating at said sense node, and adapted to receive charge from said storage region and to transmit the charge to said sense node.

21. The camera according to claim 6 wherein said storage region further comprises a plurality of pixels, said pixels adapted to selectively reduce the effect of dark current as the charge is transferred from said storage region.

22. The camera according to claim 21 wherein a portion of said pixels comprises more than one configuration adapted to transport charge through said pixels and representative of a portion of dark current.

23. The camera according to claim 22 wherein said plurality of pixels has columns adapted to transport charge, a portion of the columns has substantially equal numbers of each more than one configuration such that the charge transported through the columns contacts the same portion of dark current from each of the more than one configurations.

24. The camera according to claim 1 comprising a variable frame rate.

25. The camera according to claim 24 further comprising an output signal having a plurality of lines, a portion of which lines are active and a portion of which lines are inactive, and a plurality of line intervals, said plurality of line intervals in combination representative of a reference frame rate, wherein said plurality of line intervals are adapted to receive said lines and the frame rate is varied by altering a number of line intervals per frame.

26. The camera according to claim 25 wherein a subset of said varied lines are inactive.

27. The camera according to claim 25 wherein the frame rate is communicated to other devices by means of encoding a portion of an image signal.

28. The camera according to claim 1 wherein said camera is switchable between an interlace-scan mode and a progressive-scan mode.

29. The camera according to claim 28 further comprising more than one electrode disposed in each of the plurality of pixels, a number of said electrodes disposed in each of said plurality of pixels being selectable such that a number of rows of said plurality of pixels is varied.

30. The camera according to claim 29 wherein four electrodes are disposed in each of said plurality of pixels during the interlace-scan mode.

31. The camera according to claim 29 wherein two said electrodes are disposed in each of said plurality of pixels in the progressive-scan mode.

32. The camera according to claim 29 wherein three said electrodes are disposed in each of said plurality of pixels in the progressive scan mode.

33. A method for reducing the resistance of an imaging region of a solid-state image sensor having a plurality of pixels comprising electrodes to decrease the time period for a transfer of charge from the imaging region through a charge transport material, the method comprising the steps of:
establishing an optically-similar electrode geometry in each of said plurality of pixels; and
selectively connecting the electrodes to a phased voltage such that each electrode responds to a predetermined phased voltage and electrically communicates with the charge transport material effectuating charge transfer through the charge transport material.

34. A method for reducing an effect of dark current generated in a storage region of an image sensor, where charge transport through the storage region is effectuated through channels of a plurality of pixels using more than one electrode, each of the more than one electrode responsive to a phased voltage to transport charge vertically through the channels of the plurality of pixels, the method comprising the steps of:
transferring charge from an imaging region to channels and rows of the plurality of pixels in the storage region;
selectively connecting each of the plurality of pixels in the storage region such that a portion of the plurality of pixels in each channel is in electrical communication with a portion of a predetermined pattern of the more than one electrodes representative of a dark current of that predetermined pattern; and
transferring charge through of the channels such that the charge so transferred is in electrical communication with the predetermined pattern, thus the charge so transferred will be exposed to the dark current represented by the predetermined pattern where the predetermined pattern of the more than one electrodes is arranged to give similar dark current to each pixel.

35. A method of fabricating a mirror-image circuit having an axis of reflection disposed between two mirror images, such that a relative misalignment of component elements of the two mirror images will not alter the performance of the two mirror images relative to each other, the method comprising the steps of:
identifying critical spacings between the component, where the critical spacings are representative of a spacing that affects a portion of the performance;
selectively disposing the critical spacings such that the relative misalignments along an axis parallel to the axis of reflection will not alter performance; and
selectively disposing the component elements having critical spacings along an axis perpendicular to the axis of reflection in pairs such that the relative misalignments along the axis perpendicular to the axis of reflection will not alter performance.

36. The method according to claim 35 wherein said circuit is a buffer having more than one transistor.

37. The method according to claim 36 wherein each said transistor comprises:
a channel stop;
a gate having sides, said gate and said channel stop having a specified channel-to-gate spacing disposed along an axis parallel to an axis of reflection;
a source disposed on one side of said gate;
a drain disposed on the opposite side of said gate; and
selective contacts being disposed on said sides of said gate, said selective contacts and said gate having a specified contact-to-gate spacing disposed along an axis perpendicular to said axis of reflection, such that said source and said drain of each said transistor are disposed in pairs on one said side of said gate and relative misalignments do not adversely affect the performance of said source and said drain, whereby any relative misalignment of the component parts of said transistor will not affect performance of one said transistor relative to another said transistor.

38. A solid-state frame transfer image sensor comprising pixels in an imaging region and in a storage region, said image sensor comprising:
a charge transport layer;
channel stops disposed in the charge transport layer defining channels for charge transfer therebetween;
two or more staggered electrode layers overlying said charge transport layer, each said electrode layer comprising a patterned geometry such that a configuration of the electrode layers in each of the pixels is substantially similar;
an insulating layer overlying said electrode layers, said insulating layer having discontinuities defining holes; and
a shunt overlying said insulating layer selectively contacting said electrode layer through conductive paths formed in said insulating layer discontinuities, said shunts being selectively responsive to a phased voltage to transfer the charge from said imaging region to said storage region.

39. An image sensor adapted to translate image-bearing light into an electrical signal comprising:
an imaging region adapted to receive image-bearing light on a plurality of pixels;
a charge transport layer disposed in each of said plurality of pixels adapted to generate charge from the image-bearing light and transport charge through said imaging region as the electrical signal; and
more than one electrode, each said electrode being disposed transversely on said imaging region in a staggered relationship to one another, each said electrode being electrical insulated from other said electrodes and having a periodic geometry such that a portion of each said electrode overlying each of the plurality of pixels has a substantially similar geometry such that there are formed pixels having a substantially similar optical performance.

40. An image sensor according to claim 39 wherein said staggered relationship is a patterned relationship.

41. An image sensor according to claim 39 wherein said electrodes are phased and are in selective electrical communication with a respective one or more of said plurality of pixels such that each said phased electrode is responsive to a predefined phase to transfer the charge through said charge transfer layer.

42. An image sensor according to claim 39 further comprising more than one channel stop, said channel stops spaced apart and disposed longitudinally in said imaging region, each of said channel stops interposed between one said charge transfer layer and an adjacent said charge transfer layer to define channels there between.

43. An image sensor according to claim 42 wherein each said electrode comprises a transverse portion which extends across said charge transfer layer and said channel stops, and depending extensions which extend from the transverse portion of each said electrode in a direction parallel to said channel stops and overlying at least a portion of said channel stops.

44. An image sensor according to claim 42 wherein each said electrode comprises a finger extending from said transverse portion, said finger disposed in one of said pixels in a direction parallel to said channel stops.

45. An image sensor according to claim 42 wherein said extensions overly only said channel stop.

46. An image sensor according to claim 42 further comprising:
a shunt; and
a contact between one said extension and said shunt.

47. An image sensor according to claim 46 further comprising a storage region comprising at least one bus providing an electrical connection to said shunt.

48. An image sensor according to claim 47 further comprising package leads in said storage region, said package leads tied to said busses to reduce the resistance of the imaging region.

49. An image sensor according to claim 44 wherein said shunts are narrower than said buses.

50. An image sensor according to claim 39 wherein each of said pixels is substantially similar in responsiveness to the image-bearing optical radiation.

51. An image sensor according to claim 39 wherein a portion of said pixels are electrically responsive to a different applied voltage.

52. An image sensor according to claim 39 further comprising:
at least two shunts spaced apart from one another and disposed longitudinally on said imaging region, over at least a portion of said electrode; and
an insulator selectively interposed between said shunts and said electrode, said insulator disposed such that said plurality of pixels are selectively insulated from said shunts.

53. An image sensor according to claim 52 wherein a portion of said insulator comprises discontinuities to define holes for the formation of selective contacts.

54. An image sensor according to claim 39 further comprising a storage region adjacent said imaging region adapted to receive charge from said imaging region during a blanking period.

55. A method for decreasing internal reflection of visible light in an imaging region of an image sensor having reflective surfaces, said method comprising the steps of:
defining reflective surfaces on the imaging region of said image sensor;
disposing a red filter on each said reflective surface;
disposing a blue filter overlying each said red filter, such that said red filter and said blue filter in combination absorb substantially all incident optical radiation to decrease internal reflection.

56. A method of reducing the capacitance of a sense node in the well portion of an image sensing device, said method comprising the step of depleting the well portion of electrical charge by placing said well into electrical communication with the sense node.

57. A method for varying a frame rate of a camera having a plurality of pixels, at least a portion of said pixels disposed to collect image-bearing light, said method comprising the steps of:
providing a desired frame rate;
defining a line interval having inactive lines and active lines, said line interval representative of the desired frame rate;
collecting image-bearing light by said portion of pixels;
generating a charge in said portion of pixels;
providing the active lines with said charge;
determining a number of inactive lines of said line interval; and
transferring as a signal the inactive lines and the active lines as a frame representative of the image-bearing light having the desired frame rate.

58. A method of switching between an scan modes in a camera having a plurality of pixels, said method comprising the steps of:
providing two or more electrodes disposed within each of the plurality of pixels, each said electrode having a configuration;
defining a smallest common repeating number representative of a type of number of the configurations of said electrodes disposed near each other;
providing contacts on at least one of said electrodes within each of said smallest common repeating number, said contact adapted to allow said electrode portion to selectively receive a voltage;
selectively defining a number of rows of the plurality of pixels that is a multiple of the smallest common repeating number, such that the number of rows of said pixels is selectable, and
selectively contacting said electrodes within each of the rows of the plurality pixels selected with a voltage to effectuate charge transport through the plurality of pixels.
